(19) United States
(12) Patent Application Publication
(10) Pub. No.: US 2011/0143271 A1
(43) Pub. Date: Jun. 16, 2011

(54) PATTERN GENERATING METHOD AND PROCESS DETERMINING METHOD

(76) Inventors: Takeshi KOSHIBA, Mie (JP); Hidefumi Mukai, Kanagawa (JP); Kazuhito Kobayashi, Kanagawa (JP); Takumi Ota, Kanagawa (JP)

(21) Appl. No.: 12/822,716

(22) Filed: Jun. 24, 2010

(30) Foreign Application Priority Data
Dec. 10, 2009 (JP) 2009-280937

(51) Int. Cl. G03F 7/20

(52) U.S. Cl. 430/30

(57) ABSTRACT

A pattern generating method includes obtaining an on-substrate pattern by performing a process for forming the on-substrate pattern by simulation or experiment based on a design pattern of the on-substrate pattern formed by an imprint process using a template, employing the design pattern when a comparison result of the design pattern and obtained on-substrate pattern satisfies a predetermined condition, and correcting the design pattern to satisfy the predetermined condition when the comparison result does not satisfy the predetermined condition.

### CROSS-REFERENCE TO RELATED APPLICATIONS

This application is based upon and claims the benefit of priority from the prior Japanese Patent Application No. 2009-280937, filed on Dec. 10, 2009; the entire contents of which are incorporated herein by reference.

### BACKGROUND

1. Field

The embodiments of the present invention relates to a pattern generating method and a process determining method.

2. Description of the Related Art

In recent years, a photo-nanoimprint method of transferring a form of a master above a transferring target substrate has attracted attention. In the photo-nanoimprint method, the form of the master (template) on which a pattern to be transferred is formed is pressed against a photo-curable resist material layer that is applied on a substrate such as a wafer. Then, the photo-curable resist material layer is irradiated with light to cure the resist material layer, thereby transferring the pattern onto the resist material (for example, Japanese Patent Application Laid-open No. 2001-68411 and Japanese Patent Application Laid-open No. 2000-194142).

In the photo-nanoimprint method, the template is held above the substrate until a fine pattern of the template is filled with the resist material. At this time, in order to eliminate a non-fill defect of the pattern, it is needed to lengthen a holding time from the time the template is brought into contact with the resist material to the time the light irradiation is performed to thereby completely fill the pattern of the template with the resist material. However, when the holding time is lengthened more than necessary, a problem arises such as reduction of throughput.

Moreover, the time until grooves of the template are completely filled with the resist material depends on a pattern size. For example, when there are two types of a large pattern and a small pattern, the small pattern is filled with the resist material in a shorter time than the large pattern. In other words, the small pattern reaches a filling end level in a shorter time than the large pattern.

In a microfabrication technology using a photolithography that is currently used in a mass production site of a semiconductor device, a sophisticated lithography designing is performed using a resolution enhancement technology that includes a processing bias (pattern dimension conversion difference) correction and a proximity correction with the miniaturization of the pattern size. This is because a precise pattern formation in each process has become difficult with the progress of miniaturization of the pattern and thus a problem arises that a final finished dimension does not become as a design pattern. For example, there is a case of using a design rule (DR) in which resolution equal to or less than a half of an exposure wavelength is required. In such a case, in designing of the lithography process condition, it is needed to consider not only the proximity effect in the photolithography but also a processing bias and a fluctuation component in a photolithography process including a mask process, a resist process, and an exposure apparatus utilization technology, an etching process, and the like. Therefore, it is needed to provide design constraints on a semiconductor pattern or a design layout and check and ensure the design layout while taking into account the above.

Specifically, a designer performs a pattern designing and a pattern layout based on the design constraints in which a processing bias and the proximity effect in each process are taken into account. Then, a lithography engineer generates a mask pattern that is different from a design pattern so that the final finished dimension is the same as a design pattern dimension taking into account the processing bias and the proximity effect in each process with respect to the pattern data generated by the designer (hereinafter, mask data process).

Such mask data process includes an Optical Proximity Correction (OPC) process for correcting an Optical Proximity Effect (OPE) and the like in addition to a Mask Data Preparation (MDP) process of changing the mask pattern by using graphics operation processing, a Design Rule Checker (DRC), and the like. The mask pattern is appropriately corrected so that the final finished dimension becomes a desired dimension by performing these processes. Moreover, it is checked by an optical simulation or the like whether all patterns subjected to the OPC process based on a model or a rule that is predetermined can be formed above a substrate with a predetermined spec, and verification is performed. Whereby, it is ensured that a layout pattern can be patterned with a predetermined tolerance. These processes are called a lithography compliance check (LCC). Such a method of determining the DR and the layout in the patterning by using the photolithography is proposed, for example, in Japanese Patent Application Laid-open No. 2002-26126 and Japanese Patent Application Laid-open No. 2004-30579.

However, a component technology of an imprint lithography is different from the photolithography, so that a constraint condition for designing, a rule used in the layout checking, a Hot Spot that needs to be managed, and the like are different. Therefore, a desired pattern formation cannot be performed by applying the method of determining the DR and the layout in Japanese Patent Application Laid-open No. 2002-26126 and Japanese Patent Application Laid-open No. 2004-30579 to the photo-nanoimprint method in Japanese Patent Application Laid-open No. 2001-68411 and Japanese Patent Application Laid-open No. 2000-194142. Thus, the desired pattern formation cannot be performed even by using a mask data process flow based on a conventional layout designing method. This is because when the pattern formation is performed by using the imprint lithography, the proximity correction, the processing bias correction, and the management of the Hot Spot different from a patterning method using a conventional photolithography is needed.

### BRIEF SUMMARY OF THE INVENTION

A method of generating a pattern according to an embodiment of the present invention comprises: preparing a design pattern of a pattern above substrate formed by performing an imprint process using a template on a substrate; obtaining the pattern above substrate by performing a process for forming the pattern above substrate by simulation or experiment based on the design pattern; comparing the design pattern with obtained pattern above substrate and determining whether a comparison result satisfies a predetermined condition; and employing the design pattern when the comparison result satisfies the predetermined condition and correcting the design pattern to satisfy the predetermined condition when the comparison result does not satisfy the predetermined condition.

### BRIEF DESCRIPTION OF THE DRAWINGS

FIG. 1 is a diagram for explaining a concept of an NIL information determining process according to a first embodiment;

FIG. 2A to FIG. 2E are diagrams illustrating NIL process steps according to the first embodiment;

FIG. 3A to FIG. 3C are diagrams illustrating a template forming process when a defect occurs on a processing target film;

FIG. 4 is a flowchart illustrating a template forming procedure;

FIG. 5A to FIG. 5D are diagrams for explaining a defect modification;

FIG. 6 is a flowchart illustrating an NIL process procedure;

FIG. 7A to FIG. 7F are diagrams for explaining a filling process;

FIG. 8 is a diagram for explaining a non-fill defect density;

FIG. 9 is a diagram for explaining an application position of a resist used in the NIL;

FIG. 10A to FIG. 10J are diagrams illustrating a patterning process procedure to a wafer;

FIG. 11 is a diagram for explaining processing bias factors that contribute to a dimensional fluctuation in the NIL in the first embodiment and the proximity effect;

FIG. 12 is a flowchart illustrating a procedure for determining a pattern or a process condition used in the NIL in the first embodiment;

FIG. 13 is a diagram illustrating a relationship between a resist pattern dimension formed by performing a proximity correction and a pattern dimension that cannot be formed on a template;

FIG. 14 is a diagram illustrating a relationship between a finished pattern dimension after processing the template and the pattern dimension that cannot be formed on the template in the NIL in the first embodiment;

FIG. 15 is a diagram illustrating a relationship between a processing bias of a final template processed dimension and a space pattern dimension;

FIG. 16 is a diagram for explaining the processing bias in an imprint process;

FIG. 17 is a diagram for explaining a concept of releasing;

FIG. 18A and FIG. 18B are diagrams for explaining a layout modification;

FIG. 19 is a flowchart illustrating a correction procedure of template data;

FIG. 20 is a flowchart illustrating a procedure for determining the pattern or the process condition used in the NIL in the first embodiment by using a simulation;

FIG. 21A to FIG. 21G are diagrams illustrating a template manufacturing process according to the second embodiment;

FIG. 22 is a diagram for explaining the processing bias factors that contribute to the dimensional fluctuation in the NIL in the second embodiment and the proximity effect;

FIG. 23 is a flowchart illustrating a procedure for determining the pattern and the process condition used in the NIL in the second embodiment;

FIG. 24 is a diagram illustrating a relationship between a pattern size and a filling time of an imprint resist;

FIG. 25 is a diagram illustrating a relationship between the finished pattern dimension after processing the template and the pattern dimension that cannot be formed on the template in the NIL according to the second embodiment;

FIG. 26 is a flowchart illustrating a correction process procedure of parent template data; and

FIG. 27 is a flowchart illustrating a procedure for determining the pattern or the process condition used in the NIL in the second embodiment by using a simulation.

### DETAILED DESCRIPTION

Exemplary embodiments of the present invention are explained in detail below with reference to the accompanying drawings. The present invention is not limited by the embodiments.

### First Embodiment

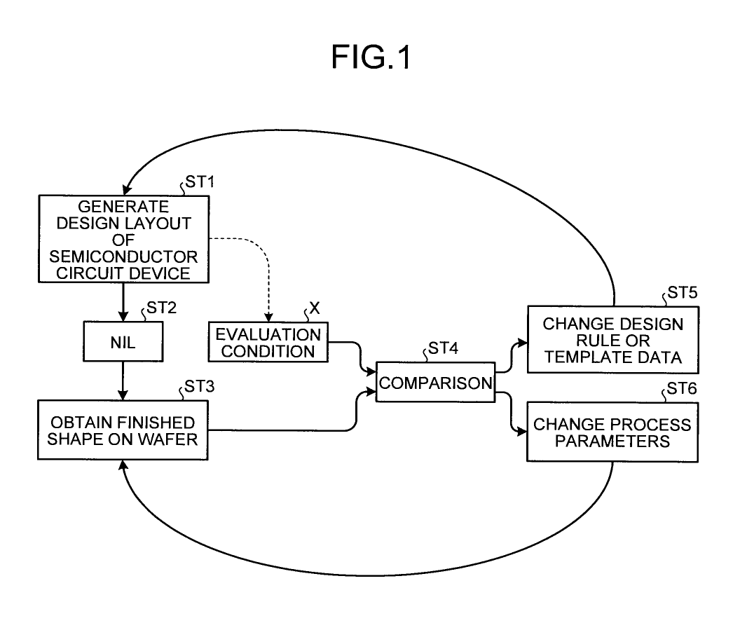

First, a concept of a pattern generating method and a process determining method according to the present embodiment is explained. FIG. 1 is a diagram for explaining the concept of an NIL information determining process according to the first embodiment. NIL information is various information used in an imprint lithography such as a nanoimprint lithography (NIL) and is, for example, a design layout (design pattern) that is a circuit layout, template data (EB lithography data), a design rule (DR), and a process parameter (process condition). The process parameter includes any of process parameters of a process when generating a template, a transferring process of transferring a pattern onto a wafer by using the template, and a processing process of obtaining a pattern by processing a processing target film above the wafer by using the transfer pattern.

As a manufacturing process of a semiconductor integrated circuit device (semiconductor device), the design layout of a semiconductor circuit device is generated to satisfy the defined DR (ST1). A template (master) for the NIL is generated by using the generated design layout.

An imprint process (NIL) is performed by using the design layout in accordance with predetermined process parameters (ST2) to obtain information on a finished shape on a wafer (ST3).

In FIG. 1, the NIL (ST2) includes a template forming process of forming a template pattern on the template, a wafer imprint process of forming a resist pattern by transferring the template pattern onto a resist material applied on the wafer (wafer substrate), and a processing process of processing the processing target film on the wafer by using the resist pattern.

The predetermined process parameters include, for example, the following parameters.
A writing process parameter that affects a proximity effect in an electron beam lithography when forming the template.
A processing process parameter that affects a processing bias (dimensional difference of the pattern before and after processing) when processing and forming the template pattern by using a written mask pattern. The processing process parameter is, for example, an etching gaseous species used in the processing, an etching time, or coverage of the template pattern.
A filling process parameter that affects a processing bias (dimensional difference between the template pattern and a filled pattern) by filling when filling the template pattern with a material (filling material such as the resist material) above the wafer. The filling process parameter is, for example, characteristics, such as composition, viscosity, and wettability, of the filling material, or a pressure, a filling speed, a tilt, and a filling time when bringing the template into contact with the filling material, an discharge recipe (drop condition to the wafer) of the filling material, and the like. The drop condition of the filling material to be filled on the wafer is, for example, a drop position or a drop volume of the filling material.
A curing process parameter that affects a processing bias (dimensional difference of the filled pattern before and after curing) when curing the filled pattern by irradiating the filled pattern with light. The curing process parameter is, for example, a type or a content of a photo-curable agent included in the filling material, or a wavelength, an irradiation time, a dose, and the like of irradiation light used for the curing.
A releasing process parameter that affects a processing bias (dimensional difference of the filled pattern before and after releasing) when releasing the template from the filled pattern after the filling. The releasing process parameter is, for example, characteristics, such as composition, viscosity, and wettability, of the filling material, an application distribution (drop distribution) of the filling material to the wafer, or a pressure, a speed, a tilt, and the like when bringing the template into contact with the filling material.
A residual-film removing process parameter that affects a processing bias (dimensional difference before and after removing of a residual film of the pattern after releasing) when removing the residual film of the pattern after the releasing. The residual-film removing process parameter is, for example, an etching gaseous species used for etching when removing the residual film, an etching time, or coverage of the template pattern.
A process parameter that affects a processing bias (dimensional difference of the pattern before and after processing) when processing the processing target film (for example, a lower layer film or a deposited film) by using the pattern after removing the residual film. The process parameter is, for example, an etching gaseous species used for etching at the time of the processing, an etching time, or coverage of the template pattern.

The information on the finished shape on the wafer includes any of a finished pattern dimension, a finished pattern shape, and information indicating whether the finished pattern determined based thereon is a dangerous pattern. For example, the pattern of which finished pattern dimension is equal to or less than a predetermined value may not be formed by the actual mass production process and therefore is determined as the dangerous pattern. Moreover, when a distance between predetermined two patterns in the finished pattern is equal to or less than a predetermined value, theses patterns may cause a short circuit and therefore are determined as the dangerous patterns.

These information on the finished shape on the wafer can be obtained by determining the finished pattern on the wafer by simulation or experiment based on the design layout. The finished pattern above the wafer can be determined by performing a process that includes at least one of the above described predetermined process parameters by simulation or experiment. The finished pattern above the wafer can be the resist pattern or a processed pattern that is obtained by processing the processing target film.

Thereafter, the obtained finished shape is compared with a predetermined evaluation condition X (ST4) to evaluate whether the finished shape satisfies the evaluation condition X. The evaluation condition X is a dimensional threshold of a circuit pattern with which a device to be manufactured can perform a desired operation or a dimensional threshold of a circuit pattern with which a device can perform a desired operation even when variation occurs in the above predetermined process parameters at the time of manufacturing the device. In other words, the evaluation condition X is a pattern dimensional threshold for ensuring a desired process margin. When it is determined that the finished shape does not satisfy the evaluation condition X, at least one of change of the DR or the template data (ST5) and change of the above process parameters (ST6) is performed.

When the DR is changed, the changed DR is defined (fed back) as a new DR when generating the design layout. When the process parameters are changed, the changed process parameters are defined (fed back) as new process parameters when obtaining the information on the finished shape. For example, the discharge recipe of the resist to the template or the like is changed.

Whereby, at least one of the design layout, the template data, the DR, the process parameters, and the finished shape (such as a resist pattern shape, a pattern shape after etching) of the pattern formed on the wafer is checked. Then, the NIL information is changed (adjusted) so that a desired semiconductor device is formed, whereby the NIL information is determined.

It is applicable to extract the dangerous pattern (pattern that has a possibility to be a pattern failure higher than a predetermined value) that is the pattern that cannot ensure a predetermined tolerance from the design layout based on the comparison result of the finished shape and the evaluation condition X. In this case, it is determined whether the dangerous pattern satisfies a predetermined evaluation condition Y (not shown). When it is determined that the dangerous pattern does not satisfy the evaluation condition Y, the DR or at least one of the template data and the process parameters is changed. The evaluation pattern Y is, for example, the number of the dangerous patterns or the type of the dangerous pattern.

In order to perform a desired pattern formation by using the NIL, it is needed to construct a flow of defining the DR in which an appropriate rule is used with respect to the NIL and checking the processing bias in an NIL process and a flow of checking the presence or absence of a Hot Spot. In the followings, explanation is given for a defining process of the DR used in manufacturing the template, a processing bias checking process in the NIL process, a process of checking the presence or absence of the Hot Spot, and the like. In the present embodiment, explanation is given for a case of verifying the NIL in which the template to be a master is used by experiment and thereby setting various conditions related to the NIL. In the present embodiment, explanation is given for a case of applying the NIL to formation of a semiconductor device; however, the NIL can be applied to a field (device manufacturing) other than the formation of the semiconductor device.

### (NIL Process Steps)

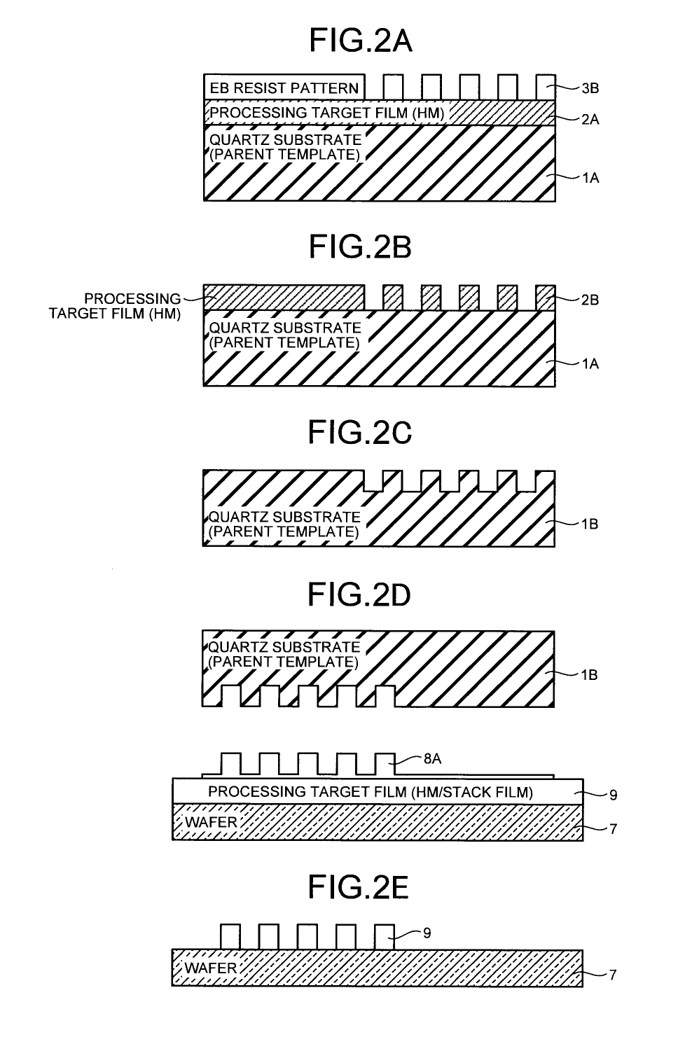

First, the NIL process steps according to the first embodiment are explained. FIG. 2A to FIG. 2E are diagrams illustrating the NIL process steps according to the first embodiment. In FIG. 2A to FIG. 2E, cross sectional views of a quartz substrate and the like are illustrated.

A pattern forming method according to the first embodiment using the NIL includes a template manufacturing process of generating the template to be a master, a wafer NIL process of forming a mask pattern above the processing target film by using the template, an imprint apparatus apparatus, and the resist material, and an etching (Etg) process of processing the processing target film from above a mask formed by the imprint. The pattern above the template used in the NIL is patterned to the same size as the circuit pattern to be formed above the wafer.

The template manufacturing process includes an EB resist patterning process shown in FIG. 2A, an HM (hard mask) etching process shown in FIG. 2B, and a quartz etching process shown in FIG. 2C. A process shown in FIG. 2D is the wafer NIL process and a wafer processing process shown in FIG. 2E is the etching process.

In manufacturing the template, as shown in FIG. 2A, a Quartz (hereinafter, Qz) blank substrate (quartz substrate 1A) used for manufacturing a photomask or the like is used. The quartz substrate 1A in this example is, for example, a 6025 blank to be the template (parent template) (master template). In the template manufacturing process, first, a processing target film 2A (processing target film for the template) to be an HM material is formed on the quartz substrate 1A, and an EB resist (not shown) is applied on the processing target film 2A.

Then, the design data is converted into a target design for template writing by performing desired data processing on the design data, and electron beam (EB) lithography is performed on the EB resist by an EB lithography apparatus by using the converted data. In the EB lithography to the template, an appropriate condition for the writing process is determined in advance by experiment or simulation. For example, in consideration of an EB proximity effect and a template processing bias, a dose (proximity correction parameter) at the time of EB irradiation is set so that a dimension of a concave pattern formed on the template becomes close to a desired target pattern. The EB proximity effect is a dimensional difference between the writing target pattern and the resist pattern obtained by the EB irradiation and development. The template processing bias is a processing bias of the pattern that occurs when processing the processing target film 2A or the quartz substrate 1A to be described later.

Whereby, a dose is modulated for each pattern or layout to be exposed. Moreover, the EB lithography is performed on the EB resist so that accuracy at a connection portion of EB shots or electron beam deflection fields is improved, for example, by using a multi-pass writing method.

The material of the EB resist used in the EB lithography is, for example, a positive-type resist for the EB lithography, and a chemically amplified resist or a non-chemically amplified resist can be used. Typically, the chemically amplified resist has a high writing throughput and a low resolution compared with the non-chemically amplified resist. The EB resist has a film thickness sufficient for processing a hard mask layer that is the processing target film 2A.

After performing the EB lithography in this manner, an EB resist pattern 3B is formed through the developing process. In the developing process, a pattern formation is performed while blur (profile blur) in the developing process being superimposed on a deposited energy distribution formed in the writing process. The blur amount for the developing process is determined by the material characteristics of the EB resist. For example, when the chemically amplified resist is used, acid in the resist is diffused by a Post Exposure Bake (PEB) performed before the developing process, so that the blur amount in the developing process becomes large.

After the EB resist pattern 3B is formed on the quartz substrate 1A, the processing target film 2A on the quartz substrate 1A is etched with the EB resist pattern 3B as a mask material. Whereby, a patterned processing target film 2B is formed (FIG. 2B). The material of the processing target film (hard mask) 2A formed on the quartz substrate 1A is preferably the material that can have a processing selectivity with respect to the Qz, and, for example, a Cr or MoSi thin film used as a light shielding film of a photomask is used. For example, when Cr is used as the material of the processing target film 2A, dry etching is performed on the processing target film 2A, for example, by using a chlorine gas with the EB resist pattern 3B as a mask.

Thereafter, a resist residue is ashed, and then the quartz substrate 1A is cleaned and the quartz substrate 1A is etched with the patterned processing target film 2B as a mask. Whereby, a patterned quartz substrate 1B is formed (FIG. 2C). When etching the quartz substrate 1A, the dry etching is performed, for example, by using a CF-based gas. An etching depth of the quartz substrate 1A is set to a depth equal to the resist height required for the resist pattern after the imprint. Moreover, a side wall angle after etching the quartz substrate 1A is preferably close to 90° with respect to the bottom surface; however, the side wall can be tapered depending on the constraints in the imprint.

After forming the quartz substrate 1B, the processing target film 2B is removed and the quartz substrate 1B is cleaned, and the quartz substrate 1B that is a 6025 blank is divided into four pieces to complete a nanoimprint template (mold). Whether to divide the quartz substrate 1B into four pieces is determined depending on a specification of a nanoimprint apparatus, and the quartz substrate 1B with the blank size can be used without performing a dicing process.

When processing the processing target film 2A or the quartz substrate 1A, the processing bias occurs. Therefore, it is applicable to control such that the dimension and the profile after processing become as desired by making correction to the writing pattern data in advance to cancel the processing bias.

Thereafter, patterning is performed on the substrate (transferring target substrate) such as a wafer 7 by using the quartz substrate 1B (parent template). The wafer 7 is a process substrate (such as a silicon substrate) for transferring the pattern formed on the quartz substrate 1B by the imprint. In this manner, in the NIL process according to the present embodiment, the pattern is formed above the wafer by using the quartz substrate 1B (parent template). It is applicable to manufacture a new template (child template) (daughter template) by once transferring the pattern of the parent template onto a different template substrate by the NIL and perform the NIL process of forming the pattern above the wafer by using this new template.

A processing target film 9 (processing target film for the wafer) (HM/Stack film) to be a hard mask material is stacked on the upper surface of the wafer 7. A photo-curable resist (wafer NIL resist) (filling material) 8A is applied on the processing target film 9 of the wafer 7. Then, the resist 8A is irradiated with light in a state where the quartz substrate 1B is pressed against the resist 8A to be patterned (FIG. 2D). Thereafter, the quartz substrate 1B is separated from the wafer 7 (releasing). After removing a resist residual film (thin film remaining on the lower portion of the resist pattern 8A) after the releasing, the processing target film 9 is etched with the patterned resist 8A as a mask, whereby the processing target film 9 is patterned (FIG. 2E).

### (Template Inspection Method and Defect Modification Method)

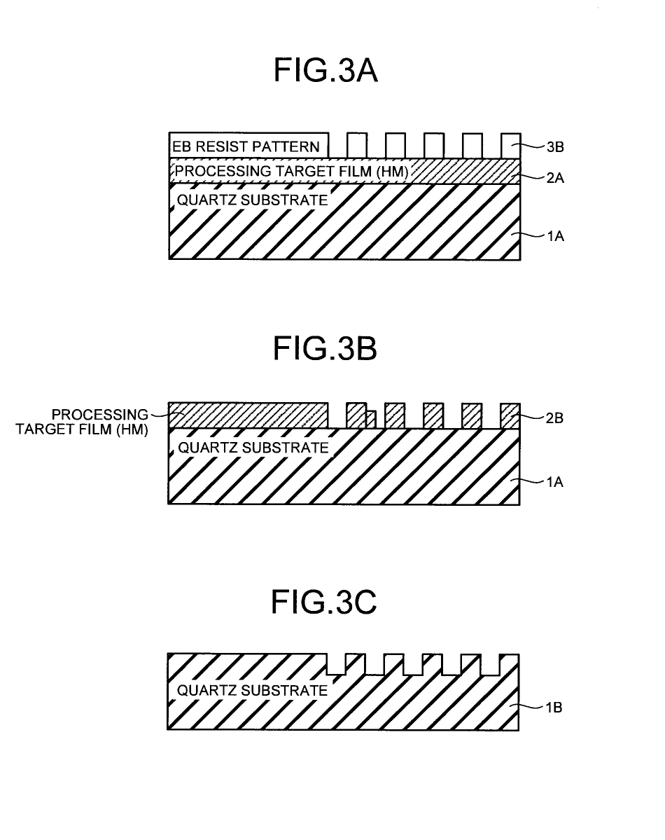

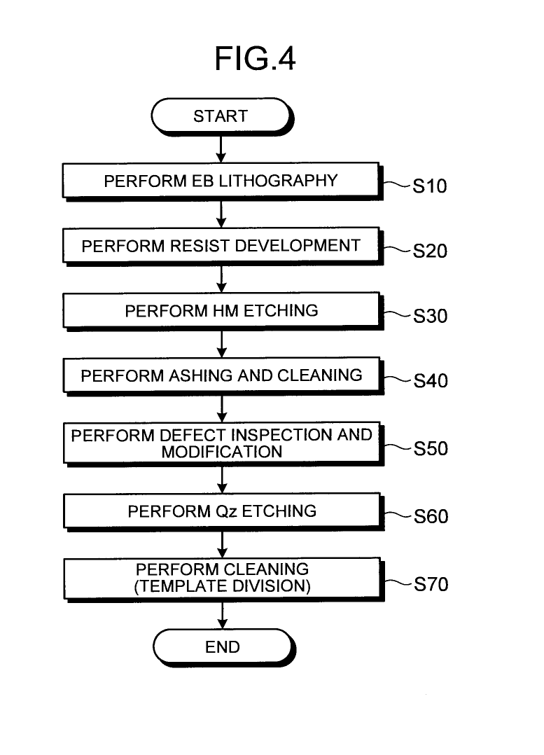

Next, the template inspection method and the defect modification method are explained with reference to FIG. 3A to FIG. 3C and FIG. 4. FIGS. 3A to 3C are diagrams illustrating the template forming process when a defect occurs on the processing target film, and FIG. 4 is a flowchart illustrating a template forming procedure.

As explained in FIG. 2A to FIG. 2E, when manufacturing the template, the EB resist is applied on the processing target film 2A formed on the quartz substrate 1A, and the EB resist is patterned by the electron beam lithography (Step S10). Then, by the resist development (Step S20), the EB resist pattern 3B is formed (FIG. 3A). Moreover, the processing target film 2A is subjected to the HM etching with the EB resist pattern 3B as a mask (Step S30), whereby the processing target film 2B is formed (FIG. 3B).

Thereafter, the remaining resist on the processing target film 2B is removed by ashing/cleaning (Step S40). Then, defect inspection/modification processes of the template are performed (Step S50).

An inspection apparatus used in the inspection of the template can be an optical system or an EB system, or a Die-to-Die system inspection apparatus or a Die-to-Database system inspection apparatus. When inspecting the template, the pattern of the processing target film 2B including unmagnified fine patterns needs to be inspected. Therefore, for example, an EB system inspection apparatus is used as the inspection apparatus excellent in resolution. The EB system inspection apparatus is used because a pattern defect present above the template is transferred with approximately the same size by the nanoimprint and therefore becomes a common defect in each shot above the wafer with extremely high possibility. In the case of the EB system, charge up of the quartz substrate 1A in the inspection can be prevented by selecting a conductive material as the material of the processing target film 2A. Consequently, a sharp SEM image can be obtained.

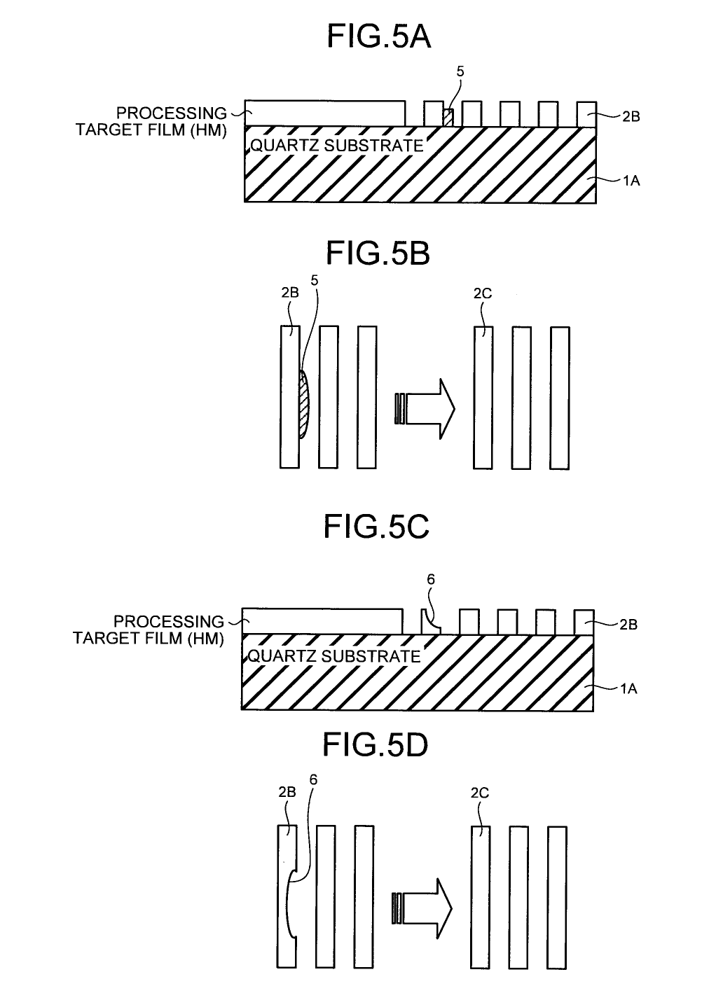

When a defect of the template is detected in the inspection process of the template, both of an opaque defect and a clear defect can be modified by using a defect modification technology performed for a photomask. For example, a defect modification example when using a halftone film of MoSi for the processing target film 2B is explained with reference to FIG. 5A to FIG. 5D. FIG. 5A to FIG. 5D are diagrams for explaining the defect modification. FIG. 5A and FIG. 5B are diagrams for explaining the opaque defect modification, and FIG. 5C and FIG. 5D are diagrams for explaining the clear defect modification. FIG. 5A and FIG. 5C illustrate cross sectional views of the quartz substrate 1A, and FIG. 5B and FIG. 5D illustrate top views of the processing target films 2B and 2C.

It is applicable to use a technology for performing ion beam etching while flowing xenon fluoride gas or a high-precision defect modification technology in which an electron beam is used for the modification of an opaque defect 5. The defect of 50 nm or less can be modified by using the electron beam.

For the modification of a clear defect 6, for example, a technology is used, in which a film (such as a C film) is deposited on the clear defect 6 by irradiating a modification portion (clear defect 6) with a beam while flowing a deposition gas. As a gaseous species at this time, a naphthalene or styrene gas is used.

After performing the defect inspection and the defect modification in these defect modification processes, the quartz substrate 1A is subjected to Qz etching with the defect-modified processing target film 2B as a mask (Step S60). Whereby, the quartz substrate 1B is formed (FIG. 3C). After etching the quartz substrate 1A, the processing target film 2B is removed and the quartz substrate 1B is cleaned, and then the quartz substrate 1B is divided, whereby the template for the nanoimprint is completed (Step S70).

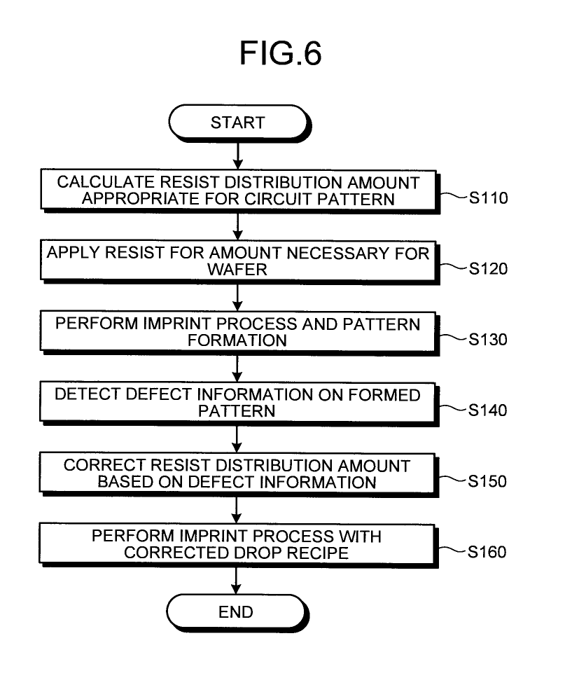

Next, explanation is given for the procedure of the NIL in which the template manufactured by the above manufacturing flow is used. FIG. 6 is a flowchart illustrating the NIL process procedure. In this example, explanation is given for the NIL in a case of using the quartz substrate 1B as the template.

The discharge recipe taking into account a density of the circuit pattern formed above the template (mold) is generated. At this time, a distribution amount of the resist 8A is calculated in advance by performing an evaporation amount compensation for the imprint resist material in the process. Whereby, the resist distribution amount appropriate for the circuit pattern is calculated (Step S110).

In accordance with the discharge recipe, the resist 8A for the amount (amount necessary for the quartz substrate 1B) in accordance with the calculated resist distribution amount is applied on the substrate (transferring target substrate) such as the wafer 7 (Step S120). In the NIL process, for example, a resist application system is employed in which the resist 8A for the amount necessary for each one shot is dropped at constant intervals by an inkjet method, so that a locally appropriate amount of the resist 8A is determined by the distribution of the resist amount to be dropped.

Explanation is given for a pattern transferring process in which a photo-nanoimprint is used. First, an appropriate amount of the resist 8A (such as a photo-curable resist material) for one shot is applied on the wafer 7, and the quartz template (such as the quartz substrate 1B) on which the pattern for one shot is formed is brought into contact with the resist 8A.

After the resist 8A is applied on the wafer 7, the template is brought close to the wafer 7 and the template is pressed against the resist 8A to wait for a predetermined time. Whereby, the drop-shaped resist 8A is filled in concaves and convexes of the template pattern. The template is held in this state until the resist material is penetrated into the fine pattern of the template. At first, filling of the resist 8A is not enough and therefore a non-fill defect occurs at corners of the pattern; however, the resist 8A fills the corners of the pattern by lengthening a holding time and the filling defects are reduced. The waiting time (hereinafter, filling time) for the filling is shorter as the pattern is finer and is long for a large pattern such as a dummy pattern or a mark.

After sufficiently filling the concaves and convexes of the template pattern with the resist 8A, UV light is emitted from immediately above the template for a predetermined time, so that resin of the resist 8A is cured (shrunk). Thereafter, the template is released by stripping from the resist 8A after being cured. Whereby, the imprint process to the resist 8A and the pattern formation to the resist 8A are performed (Step S130).

Thereafter, the wafer 7 on which the pattern is formed is carried to a wafer defect inspection apparatus to perform the defect inspection on the wafer 7. At this time, the pattern defect inspection of the Die-to-Die system or a Cell-Array system is performed by using the wafer defect inspection apparatus to detect an intrinsic defect of the NIL. Whereby, defect information on the pattern formed on the wafer 7 is detected (Step S140). When detecting the defect, the defect due to a factor other than the imprint process, such as particle and dust, is also detected. In this example, a non-fill failure defect (filling failure of the resist 8A) unique to the nanoimprint is mainly detected and extracted intensively. The non-fill failure in the nanoimprint often occurs as a common defect in a case where there is a portion in which the resist material is locally insufficient, a case where the filling time is insufficient, or the like.

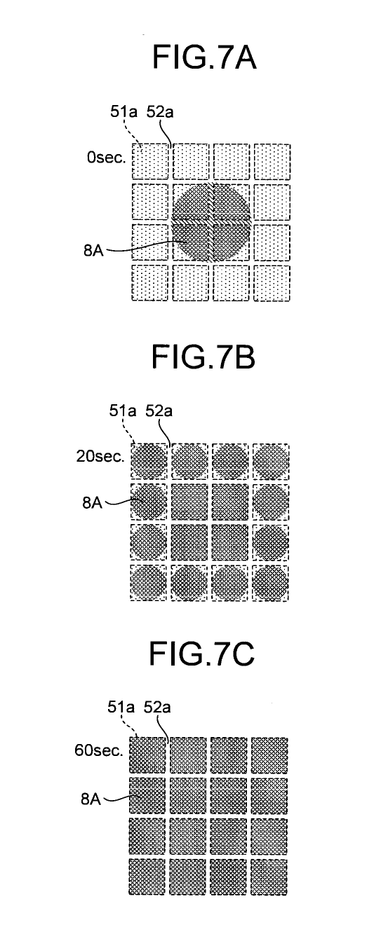

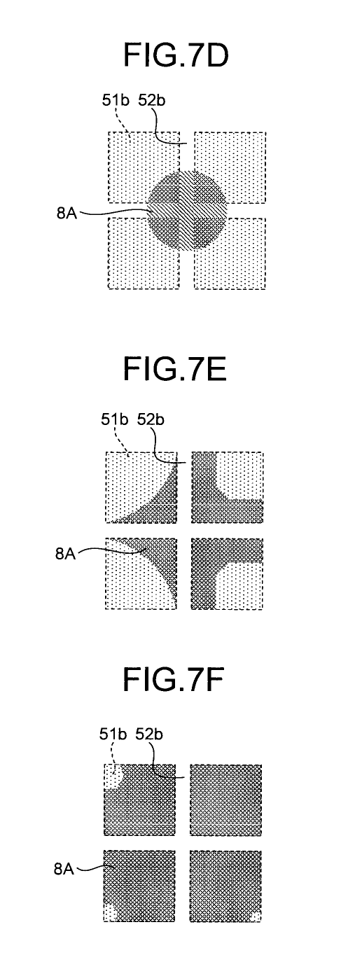

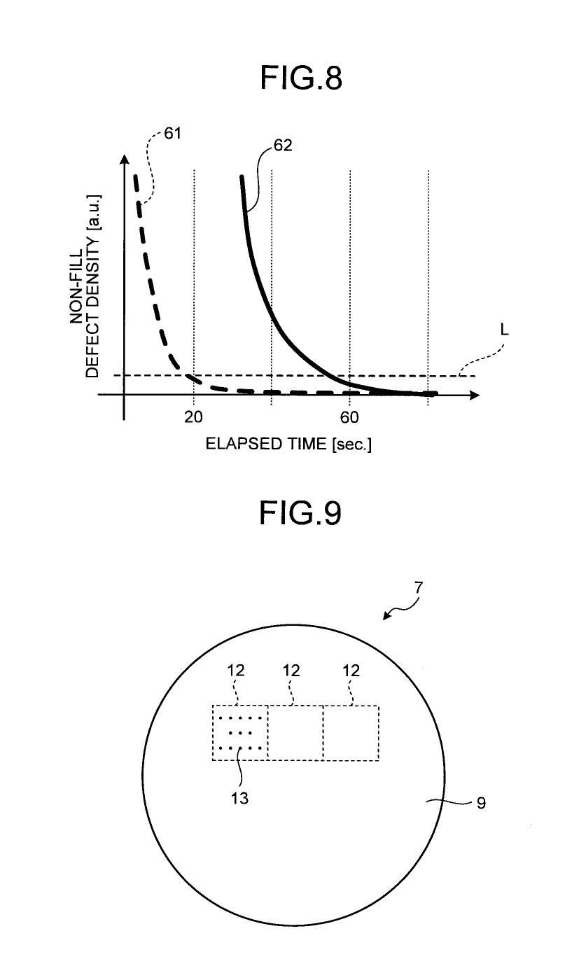

The non-fill failure defect in the nanoimprint is explained. FIG. 7A to FIG. 7F and FIG. 8 are diagrams for explaining the non-fill failure in the nanoimprint. FIG. 7A to FIG. 7F are diagrams for explaining a filling process, and FIG. 8 is a diagram for explaining a non-fill defect density.

FIG. 7A to FIG. 7C are diagrams for explaining the filling process when fine rectangular template patterns (rectangular patterns 51a) are filled with the resist 8A. FIG. 7D to FIG. 7F are diagrams for explaining the filling process when large rectangular template patterns (rectangular patterns 51b) are filled with the resist 8A. FIG. 7A and FIG. 7D illustrate a filling state of the resist 8A immediately (0 sec) after bringing the rectangular patterns 51a and 51b into contact with the wafer 7 on which the resist 8A is dropped. FIG. 7B and FIG. 7E illustrate the filling state of the resist 8A after 20 sec, and FIG. 7C and FIG. 7F illustrate the filling state of the resist 8A after 60 sec.

In FIG. 7A to FIG. 7C, the rectangular pattern 51a corresponds to a concave portion of the template and a groove 52a between the rectangular pattern 51a and the rectangular pattern 51a corresponds to a convex portion of the template. In FIG. 7D to FIG. 7F, the rectangular pattern 51b corresponds to a concave portion of the template and a groove 52b between the rectangular pattern 51b and the rectangular pattern 51b corresponds to a convex portion of the template. The rectangular pattern 51a is a fine pattern of which area is smaller than the rectangular pattern 51b.

As shown in FIG. 7A to FIG. 7C, when the rectangular patterns 51a as the fine pattern are brought close to the wafer 7, the resist 8A is spread in approximately a circular shape from the drop position of the resist 8A. When the rectangular patterns 51b as the large pattern are brought close to the wafer 7, the resist 8A is spread in approximately a circular shape from the drop position of the resist 8A. The resist 8A is filled approximately in the same area in the fine pattern and the large pattern immediately after bringing the template pattern into contact with the wafer 7.

Thereafter, when 20 sec has elapsed, the concave portions of the patterns positioned in the central area (near the drop position) in the fine pattern are filled with the resist 8A. Moreover, the resist 8A fills only near the center of each concave portion of the patterns positioned in a peripheral area (area distant from the drop position) in the fine pattern.

On the other hand, the resist 8A fills the concave portions near the convex portions in the large pattern and the concave portions positioned in the central area in the large pattern. Moreover, the resist 8A is not filled in the concave portions that are far from the convex portions in the large pattern and are positioned in the peripheral area in the large pattern.

Thereafter, when 60 sec has elapsed, the resist 8A fills almost all of the concave portions in the fine pattern. On the other hand, even when 60 sec has elapsed, the resist 8A is not filled in some portions of the concave portions that are far from the convex portions in the large pattern and are positioned in the peripheral area of the large pattern. In this manner, the filling of the resist 8A is faster as the pattern is finer and is slower in the large pattern such as a dummy pattern or a mark.

In FIG. 8, a horizontal axis indicates an elapsed time from the time the template pattern is brought into contact with the wafer 7 and a vertical axis indicates the non-fill defect density. FIG. 8 illustrates how the non-fill defect density changes along with the elapsed time, in which non-fill defect density characteristics 61 of the fine pattern (small pattern) is indicated by a dotted line and non-fill defect density characteristics 62 of the large pattern is indicated by a solid line. The fine pattern reaches a filling end level L earlier than the large pattern. Therefore, when the waiting time from the time the template is pressed against the resist 8A is short, the filling of the resist 8A is insufficient in some cases as shown in FIG. 7A.

Because processing concaves and convexes or the like due to a surface treatment are present on the wafer 7 on which various processes are performed, the non-fill failure having a wafer in-plane tendency occurs in some cases. Any non-fill failure due to the insufficient filling time and the surface treatment often becomes a large scale defect. These defects can be easily sorted, for example, by reviewing by a SEM. In this example, an example of detecting a nanoimprint intrinsic defect using an optical defect inspection apparatus is illustrated; however, the defect inspection can be performed in the similar manner also by other apparatus such as an EB system defect inspection apparatus.

After detecting the defect information on the pattern formed above the wafer 7, the detected defect information is fed back to the application amount (distribution amount) of the resist 8A. When extracting the defect information, the defect information can be extracted from the resist pattern or the defect information can be extracted from the pattern obtained by processing the processing target film from above the resist pattern. Among the detected defects, for example, only information (defect information) on the defect unique to the nanoimprint and the non-fill defect is extracted. Specifically, as the defect information, information on positional coordinates of the defect and a defect size thereof are extracted.

A locally-insufficient resist application amount is estimated based on these defect information and a new resist application amount is set. The discharge recipe for applying the resist 8A by the newly-set resist application amount is set to an applying and developing apparatus. The discharge recipe is a condition related to the filling process of the resist 8A to the template, and is, for example, the drop condition (such as the drop position and the drop volume) of the resist 8A to the wafer 7. The discharge recipe can include the characteristics, such as composition, viscosity, and wettability, of the resist 8A to be filled.

Whereby, the applying and developing apparatus adjusts and controls the application amount of the resist 8A in accordance with the discharge recipe with the new resist application amount. In other words, the resist application distribution is corrected based on the defect information (Step S150). The applying and developing apparatus applies the resist 8A on the wafer 7 in accordance with the generated discharge recipe after the correction. Thereafter, the imprint process similar to Step S130 is performed (Step S160).

The above processes at Steps S110 to S160 are repeated until the non-fill failure disappears, thereby enabling to generate the discharge recipe in which the processes are optimized more precisely.

Moreover, in addition to the above discharge recipe, it is applicable to determine a distance (hereinafter, template distance) between the template and the wafer 7, the filling time, other control parameters of an imprint apparatus related to the imprint process, and the like. The template distance, the filling time, other control parameters of the imprint apparatus, and the like are set in accordance with the flowchart shown in FIG. 6. Whereby, the NIL condition setting is completed.

### (Patterning on Wafer)

Next, a process flow is explained in which the resist 8A on the wafer 7 is patterned by using the above imprint process procedure and the processing target film 9 on the wafer 7 is processed with the patterned resist 8A as a mask.

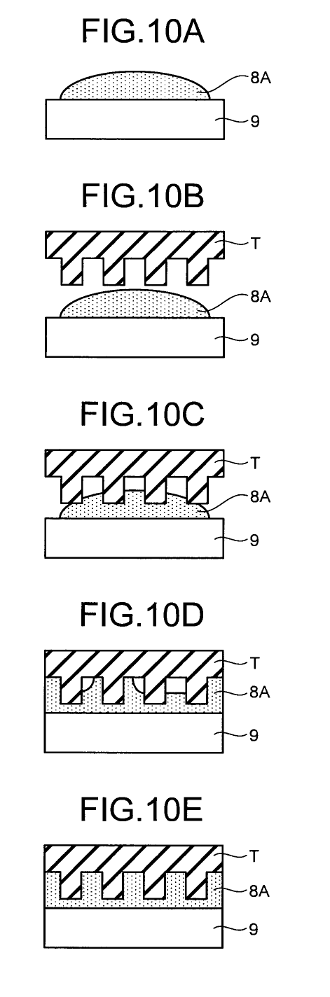

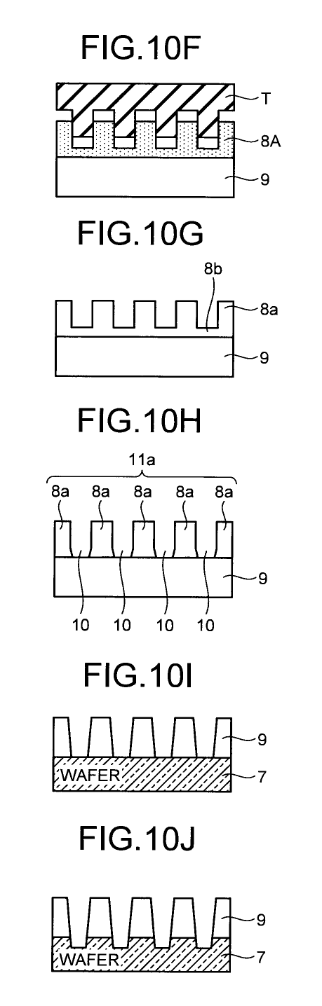

FIG. 9 is a diagram for explaining an application position of the resist used in the NIL, and FIG. 10A to FIG. 10J are diagrams illustrating a patterning process procedure to the wafer. FIG. 9 illustrates a top view of the wafer 7 to be a processing target substrate, and FIG. 10A to FIG. 10J illustrate cross sectional views in the pattern forming process in which the imprint is used. In FIG. 10A to FIG. 10H, the wafer 7 as a lower layer of the processing target film 9 is not shown.

As shown in FIG. 9, the above optimized resist 8A for the imprint is applied on an area 12 for one shot on the processing target film 9 formed on the wafer 7. The resist 8A is applied by dispersing droplets 13, 13, . . . composed of a photo-curable organic material for each area 12. The resist 8A is applied, for example, by dispersing resist material droplets in the inkjet method. FIG. 10A illustrates an enlarged view of one droplet portion (resist 8A) of a plurality of the dispersed droplets 13.

The amount of the resist 8A to be applied is controlled based on a desired film thickness of a concave-portion organic film 8b to be described later. Specifically, the amount of the resist 8A to be applied is controlled by changing a distribution shape of the droplets 13, 13, . . . , a distribution density, or a size (volume) of each droplet 13. The amount of the resist 8A to be applied is adjusted to the amount sufficient for filling a space between the processing target film 9 and a template T and pattern grooves of the template T in accordance with a setting value of a distance between the processing target film 9 and the template (which is shown as the template T in FIG. 10B to FIG. 10F). Moreover, it is applicable to form a different processing target film for processing the processing target film 9 on the processing target film 9 and apply the resist 8A on this different processing target film.

Next, as shown in FIG. 10B and FIG. 10C, the template T on which the pattern for one shot is formed is brought close to the processing target film 9 to bring it into contact with the resist 8A (droplets 13, 13, . . . ). Whereby, a plurality of the droplets 13, 13, . . . shown in FIG. 9 is combined to have a film shape.

Thereafter, the template T is further brought close to the processing target film 9 and the template distance between the processing target film 9 and the template T is kept at a predetermined distance. This template distance is controlled to be equal to a film-thickness setting value of the concave-portion organic film 8b to be described later. The control of the template distance is performed with an accuracy of nanometer order by measurement of the distance between the template T and the processing target film 9 by a laser interferometer or the like and/or measurement of a pressing force of the template T by a piezo actuator, or the like.

The template distance is kept at a predetermined distance for a predetermined filling time. The resist 8A is penetrated into the grooves of the fine pattern formed on the template T by capillary action during this filling time (FIG. 10D and FIG. 10E).

Next, in a state where the template T is filled with the resist 8A, the resist 8A is irradiated with light such as ultraviolet rays. Whereby, the resist 8A is cured to be a cured organic film having a concave and convex pattern that is engaged with the pattern formed on the template T.

Thereafter, as shown in FIG. 10F, the template T is released from the cured resist 8A. As shown in FIG. 10G, the resist 8A after being cured is composed to include a patterned film on the upper layer side (convex-portion organic film 8a as convex portions) and a film (concave-portion organic film 8b) (hereinafter, referred to as a residual film in some cases) that acts as concave portions on the lower layer side. The film thickness of this concave-portion organic film 8b can be set to a desired film thickness by controlling the template distance as described above.

Next, the wafer 7 is stepped by the area 12 for one shot, and the above processes in FIG. 10A to FIG. 10G are repeated. These processes are repeated until scanning the whole surface of the wafer 7.

After patterning the resist 8A on the whole surface of the wafer 7, a breakthrough etching for removing an organic film is performed on the wafer 7 to form openings 10 by removing the concave-portion organic film 8b (residual film). As an etching gas at this time, for example, a methane-based gas (such as CHF3 gas) is used. In the breakthrough etching, a dimensional control can be performed by positively providing the processing bias. This is because when the etching is performed under the condition in which reaction products are easily generated, the etching proceeds while the reaction products are deposited on a side wall of a hole to be formed and therefore the concave-portion organic film 8b is processed into a tapered shape. With this breakthrough etching, as shown in FIG. 10H, the openings 10 are formed at the position of the concave-portion organic film 8b. The width (width of an exposed surface of the processing target film 9) of this opening 10 is set to a desired pattern dimension (pattern dimension corresponding to the design layout).

FIG. 10H illustrates a cross sectional view in a process after the breakthrough etching. As is apparent from FIG. 10H, a resist pattern 11a that includes the convex-portion organic films 8a remaining without being etched and the openings 10 is formed on the processing target film 9.

Thereafter, the processing target film 9 is etched with the resist pattern 11a as a mask. Whereby, as shown in FIG. 10I, the processing target film 9 is patterned. FIG. 10J illustrates a cross sectional view when the wafer 7 as a base substrate is processed with the patterned processing target film 9 as a mask. Because the processing target film 9 after being etched finally needs to be patterned to a desired dimension, the processing bias for each pattern of the resist 8A is confirmed in advance. Therefore, the pattern of the convex-portion organic films 8a in which the processing bias is taken into account is set as the target dimension after the NIL.

In order to correct and modify the target dimension after the NIL, it is sufficient to perform an appropriate correction on the design data in advance for controlling the template dimension. For example, the processing condition is optimized so that the processing bias is suppressed as much as possible with respect to a cell portion that is the finest high-density pattern. Therefore, the processing bias is calculated in advance for the pattern of a peripheral circuit or an extraction area other than the cell portion. Then, a mask data preparation (hereinafter, MDP process) is performed, in which an appropriate graphics operation is performed on a plurality of the patterns on the design data. As the MDP process, for example, model-based operation processing can be performed based on the processing bias model. When the processing target film 9 is a stacked film, for example, a final processed dimension of the processing target film 9 is compared with the pattern dimension after the NIL and this dimensional difference is set as a processing bias rule.

For an etching apparatus (etcher) and an etching condition when performing the breakthrough etching and the processing target film etching explained in FIG. 10A to FIG. 10J, the etchings can be performed with different etching devices and different etching conditions or with the same etching device and the same etching condition. Whereby, a desired semiconductor pattern can be obtained.

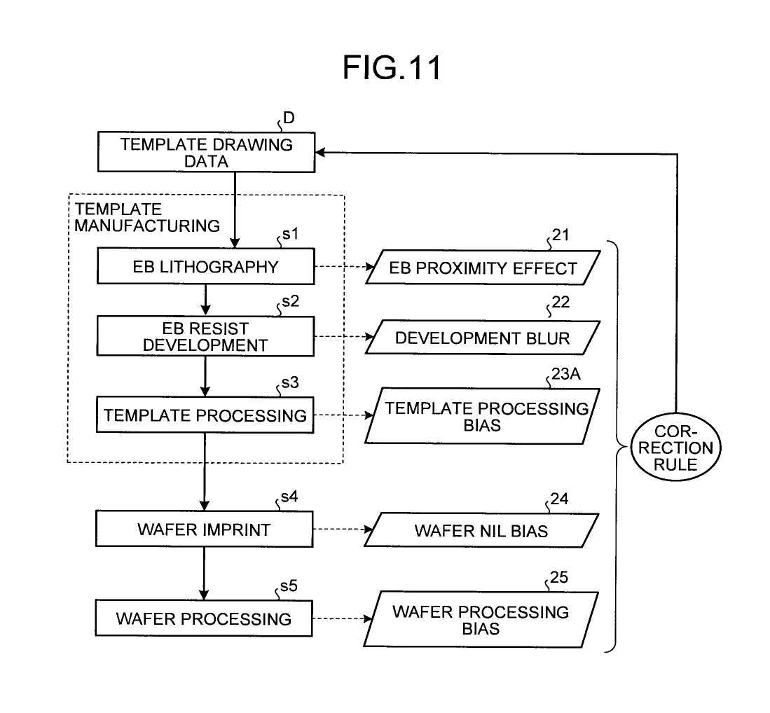

Next, a method of determining at least one of the circuit layout, the template data, the DR, and the process parameters used for manufacturing a semiconductor device by the NIL is explained with reference to FIGS. 11 to 17.

### (Dimensional Fluctuation Factors in NIL According to First Embodiment)

FIG. 11 is a diagram for explaining processing bias factors that contribute to the dimensional fluctuation in the NIL in the first embodiment and the proximity effect. FIG. 11 illustrates the dimensional fluctuation factors from the template manufacturing to the end of the wafer processing.

The EB lithography data that is the template data generated by performing the MDP process on the design data is generated as template writing data D in advance. In the template manufacturing, the EB lithography (s1) is performed to write the pattern corresponding to the template writing data D above the Qz blank substrate.

Thereafter, the energy distribution (latent image distribution) deposited in the EB resist by the EB lithography becomes the pattern of the EB resist 3B through the PEB process and the EB resist developing process (s2). Then, the HM (processing target film 2A) is processed and patterned, and template processing (s3) is performed by processing the Qz blank substrate with the processing target film 2B after patterning as a mask. Then, the template is completed by stripping the HM. The template writing data D is generated in advance following a correction rule in which the proximity effect (EB proximity effect 21) in the EB lithography, a development blur 22 in the EB developing process, and a template processing bias 23A through a processing process on the template in the template manufacturing processes (s1 to s3) are all considered.

Thereafter, the wafer imprint (s4) is performed on the wafer 7 by using the template that is finished as desired to form an imprint resist pattern. The processing target film 9 is etched with this imprint resist pattern as the HM, whereby formation of a processed pattern (wafer processing) (s5) to the wafer 7 is performed. The template writing data D is generated in advance following a correction rule in which the processing bias (wafer NIL processing bias 24) in the NIL and the processing bias (wafer processing bias 25) of the processing target film 9 in the wafer patterning processes (s4 and s5) are considered. The etching of the processing target film 9 can be a processing process by a stacked HM; however, a case is explained in this example in which the wafer processing bias 25 is the processing bias to the final dimension.

In this manner, a desired processed pattern cannot be obtained unless the processing bias and the proximity effect in the template manufacturing and the processing bias in the wafer patterning process are corrected with respect to the design data by performing the MDP process. In other words, the template writing data D needs to be corrected in accordance with a correction rule based on the EB proximity effect 21, the development blur 22, the template processing bias 23A, the wafer NIL processing bias 24, and the wafer processing bias 25.

Moreover, because the template writing data D needs to be generated in the form of satisfying all of the circuit pattern in each process, the constraint condition to the layout, and the required spec, it is difficult to construct a device manufacturing process that can obtain sufficient yield unless the DR, the circuit layout, and the process parameters that cover these constraint condition and required spec are found. Therefore, the present embodiment performs generation of the template writing data D and determination of the DR and the process parameters with which sufficient yield can be obtained, by using a flow explained below.

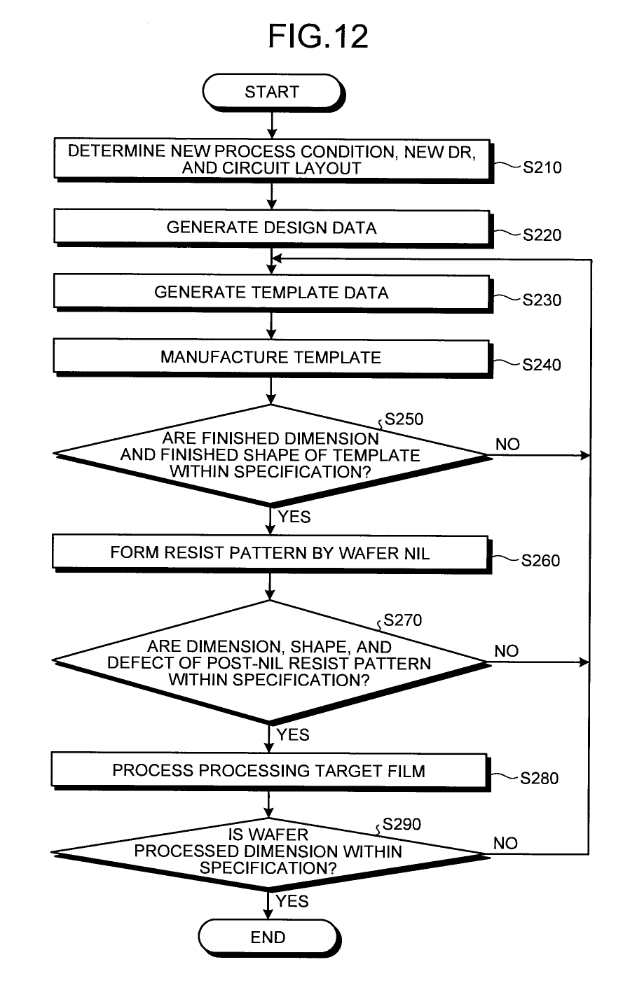

FIG. 12 is a flowchart illustrating a procedure for determining the pattern or the process condition used in the NIL in the first embodiment. FIG. 12 illustrates the flow for determining at least one of the circuit layout, the template data, the DR, and the process parameters when manufacturing a semiconductor device by using the NIL.

### (Step S210) <Determination of DR>

The pattern used in the NIL is generated, for example, by shrinking the existing pattern by using data obtained by performing compaction on previous-generation design data as an example. Specifically, a new process condition, a new DR, and the circuit layout are temporarily determined by simulation or experiment in which the processing condition and the NIL condition used in the next generation are taken into account. At this time, the DR based on the simulation or experimental data related to the template manufacturing process is also taken.

The template manufacturing process is affected by the EB proximity effect 21, the development blur 22, and the template processing bias 23A. The EB proximity effect 21 is corrected by modulating a dose for each pattern by the GHOST method or the like and performing writing. Various established correction methods exist for this technology, so that explanation thereof is omitted.

The template is a one-to-one mask, so that a desired dimensional control accuracy cannot be often satisfied with a proximity correction accuracy required for the EB lithography for manufacturing a photomask. Therefore, a resist pattern dimension as a result of performing a proximity correction by a dose modulation method is measured, and a desired pattern shape is ensured by performing Data processing (data correction) on the template writing data for a residue from the target. After performing these corrections, the DR in the template writing with which the pattern can be formed by the EB lithography is set.

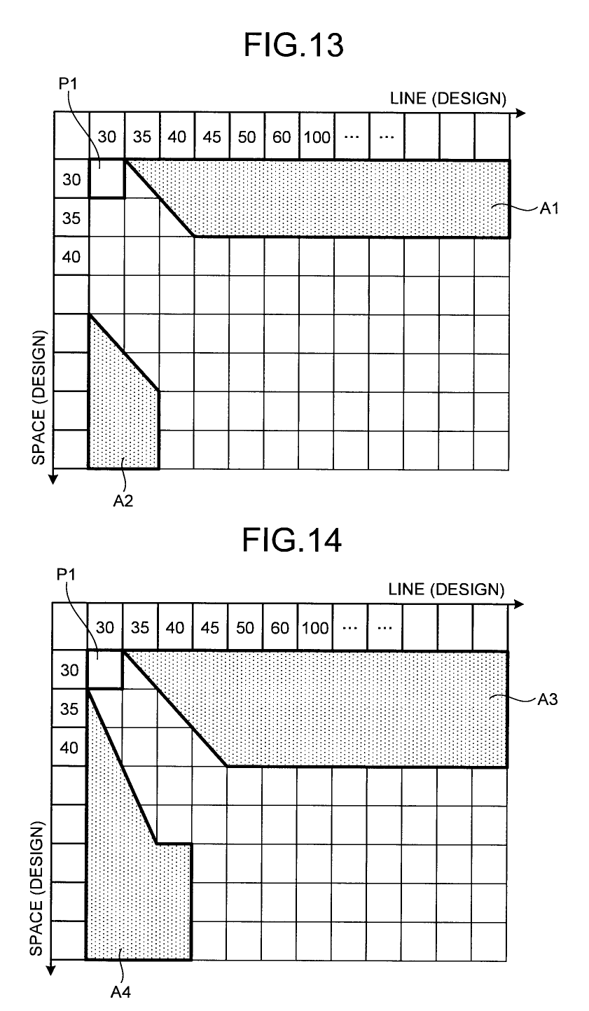

For example, dimension measurement is performed on the resist pattern that is formed by performing the proximity correction, and the DR in the template writing is set by determining a portion that is finished to a desired spec. FIG. 13 is a diagram illustrating a relationship between the resist pattern dimension formed by performing the proximity correction and the pattern dimension that cannot be formed on the template.

FIG. 13 illustrates a determination result indicating whether the resist pattern formed by performing the proximity correction on a one-dimensional line & space (LS) pattern that is a combination of numerical values of a line and a space is finished to a desired spec. The patterns in a matrix in FIG. 13 are subjected to a writing evaluation by providing a dimensional bias of the pattern, thereby enabling to accurately determine a condition that has the possibility of being finished as desired.

When the dimension of the cell portion is 30 nm and an allowable spec is ±10%, even in the case where the resist pattern is formed under a process condition where a 1:1 LS pattern (area P1 in FIG. 13) in which the line is 30 nm and the space is 30 nm can obtain the maximum writing margin, there are areas (area A1 and area A2 in FIG. 13) that cannot be formed within the spec. The patterns of the area A1 and the area A2 indicate the areas in which the pattern formation within the spec is difficult even if the data is provided with the dimensional bias. In other words, areas other than the area A1 and the area A2 shown in FIG. 13 become the DR (allowable range) in the template writing.

Moreover, when the finished dimension of the LS pattern on the matrix in FIG. 13 is evaluated in the template processing procedure, the pattern area that can be used in the template manufacturing is further narrowed by the processing bias.

FIG. 14 is a diagram illustrating a relationship between the finished pattern dimension after processing the template and the pattern dimension that cannot be formed on the template in the NIL according to the first embodiment. FIG. 14 illustrates a determination result indicating whether the pattern after processing a one-dimensional LS pattern is finished as a desired spec. For example, the patterns of an area A3 and an area A4 shown in FIG. 14 are use-prohibited areas taking into account the template constraints. Therefore, areas other than the area A3 and the area A4 shown in FIG. 14 become the DR (allowable range) in the template manufacturing.

Furthermore, because a loading effect in the template processing process has a different effect on the dimension depending on the pattern, it is often insufficient that the correction rule of the processing bias provides only a constant dimensional bias to the template data. Therefore, in the present embodiment, the processing bias rule that depends on the dimension is used.

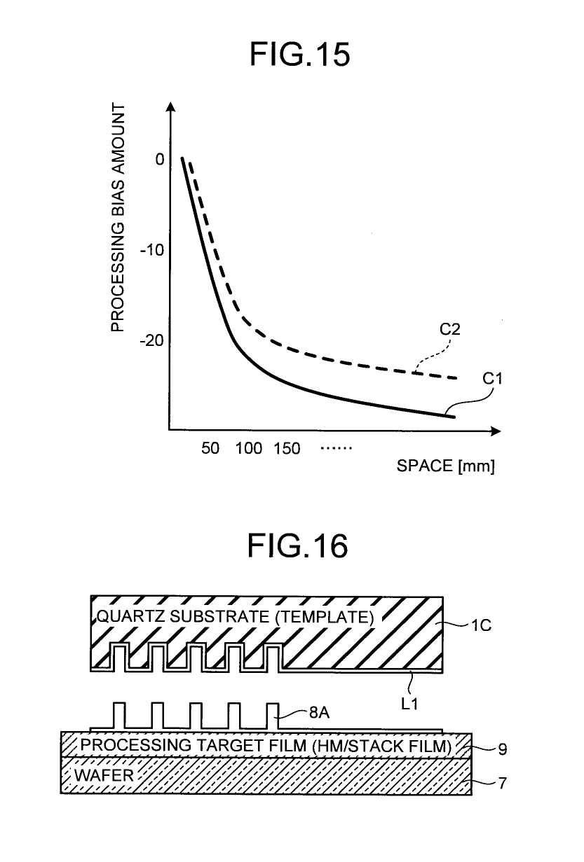

FIG. 15 is a diagram illustrating a relationship between the processing bias of a final template processed dimension and a space pattern dimension. FIG. 15 illustrates a space dependency of the processing bias in the final pattern dimension of the Qz blank substrate. In this example, the processing bias is a value with reference to the resist pattern dimension after the EB lithography, i.e., the difference between the resist pattern dimension after the EB lithography and the final pattern dimension of the Qz blank substrate.

A curve C1 indicates the processing bias (processing bias correction amount) when the template pattern is 30 nm line. A curve C2 indicates the processing bias (processing bias correction amount) when the template pattern is 50 nm line. As shown in the curves C1 and C2, it is found that there is a large processing bias that depends on the space width. Therefore, the processing bias rule is generated for each dimension based on these processing biases, and the data correction is performed for these processing biases. Whereby, a highly-accurate template can be manufactured.

In this manner, in the DR evaluation in the DR determining process of the template, for example, the data generated by shrinking the previous-generation design data is converted into the EB data to be examined. However, the template data in the NIL is mirror-reversed/black-and-white reversed with respect to a wafer pattern image. Therefore, the DR is evaluated and determined taking into account that a blank (space) portion on the wafer 7 corresponds to a remaining (line) portion on the template.

Moreover, the process parameters, the DR, and the circuit layout are determined taking into account the processing bias and the Hot Spot in the NIL process. FIG. 16 is a diagram for explaining the processing bias in the imprint process. In the NIL process, the patterning is performed by bringing the quartz substrate 1B that is the template and the resist 8A into contact with each other, so that the template needs to be released from the resist 8A. Therefore, a thin-film release layer L1 including a release material component is formed in a material contact interface of the template surface in advance in some cases to improve releasability. The thin-film release layer L1 has a thickness of, for example, about 1 nm, and is conformally formed on the whole concave and convex surface of the quartz substrate 1B. Therefore, the pattern dimension after the NIL often has a constant processing bias. In the present embodiment, the process parameters, the DR, and the circuit layout are determined taking into account this processing bias.

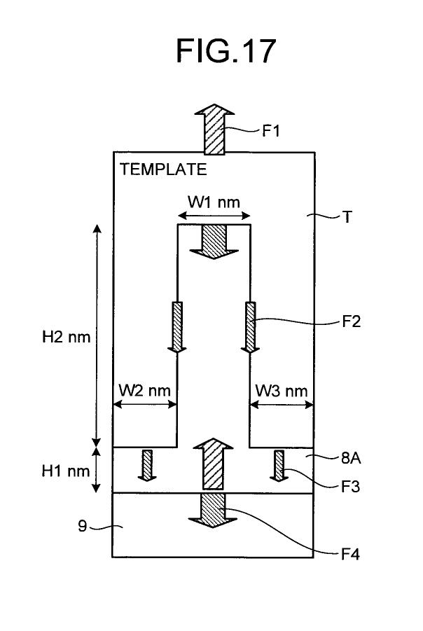

Furthermore, when the dangerous pattern is extracted by a releasability examination experiment or a releasability evaluation simulation of the circuit layout, the layout needs to be modified in some cases. FIG. 17 is a diagram for explaining a concept of the releasing. FIG. 17 illustrates the concept of the releasing by the releasability evaluation simulation or the like by a schematic cross sectional view.

In the releasing, an adhesion force (a fixing force F3 between the template and the imprint resist and a side-wall adhesion force F2) between the template and the resist 8A acts downward against a release force (template release force F1) to raise the template upward. The side-wall adhesion force F2 is a friction force due to the fixing stress. At this time, it is determined whether the releasing occurs or destruction occurs depending on the balance of the force in which an adhesion force (fixing force F4 between the resist and a lower layer film) between the resist 8A and the processing target film 9 that is the lower layer film is taken into account.

The fixing force F3 between the template and the imprint resist and the side-wall adhesion force F2 are friction forces acting on the concave and convex surface such as the side wall surface and are considered to be generated due to a fixing stress in a vertical direction with respect to the side wall. Numerical values estimated from the experimental result are applied to these forces in a simulation. It is applicable to use a value that is experimentally measured for an adhesion force related to other interfaces. For example, a solid film is formed and a substance of which adhesion force needs to be evaluated is brought into contact with the solid film from the opposite side, and a tension is measured. Qualitatively, the release force is needed which is approximately proportional to a surface area (area that is determined by W1 to W3 and H2) of the interface. A shearing force on the resist 8A in the releasing is determined from the necessary release force, the fixing stress in the interface, and Young's modulus of the material. When this shearing force becomes equal to or more than a threshold, it is considered that destruction of the resist 8A occurs and the defect (release defect) occurs.

Therefore, the parameters for the imprint process are changed (change of a process technology) or a circuit layout modification is performed to reduce the release defects extracted by experiment or simulation. Specifically, the change of the process parameters is change of the amount of the release film material or change of the imprint resist material, and the modification of the circuit layout is a layout change to reduce the surface area of the concave and convex surface, and the like. The modification of the circuit layout is performed based on at least one of the release force, the fixing stress in the interface, Young's modulus of the material, the threshold of the shearing force on the resist 8A, a release angle, the filling time of the resist 8A, a curing time of the resist 8A, an overlay error with other layers, the processing bias, and the like.

Evaluation of a filling performance can be performed in advance other than the releasability examination experiment or the releasability evaluation simulation. This is performed for setting the filling time so that the throughput needed for the device manufacturing can be achieved. When the assumed filling time is not satisfied, the change of the process parameters or the layout modification is performed.

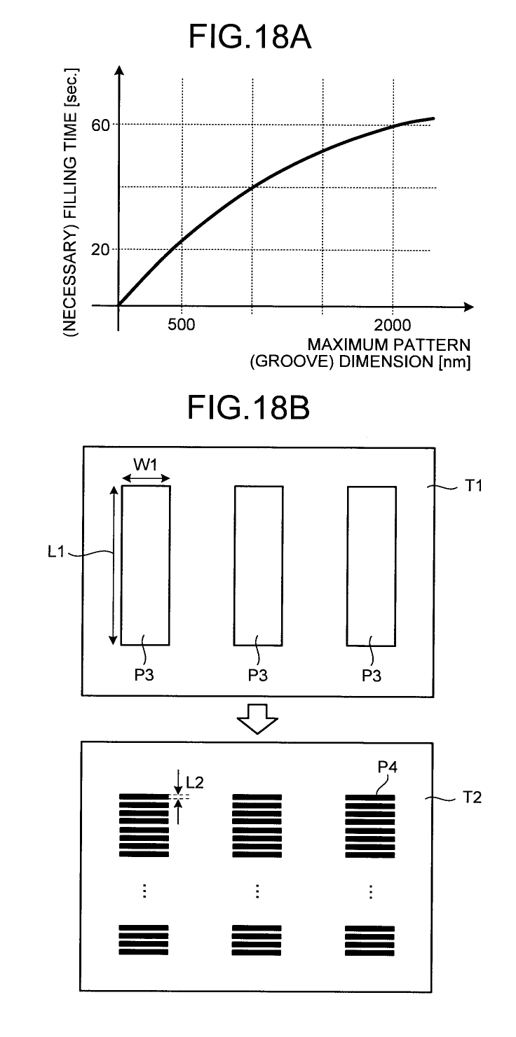

The layout modification is explained. FIG. 18A and FIG. 18B are diagrams for explaining the layout modification. FIG. 18A is a graph illustrating a relationship between a maximum space dimension on the template and the filling time of the imprint resist, and FIG. 18B is a top view of a template T1 before the modification and a template T2 after the modification.

FIG. 18A illustrates a dependency of the maximum pattern (groove) on the imprint resist filling time. The filling time becomes longer as the maximum space dimension becomes thicker. Moreover, as shown in the template T1 before the modification in FIG. 18B, when there is a pattern P3 with the space dimension of W1 (nm)×L1 (nm) above the template T1, for example, if W1 is 2 μm, the filling time becomes extremely long, so that a desired throughput cannot be satisfied. Therefore, this pattern P3 is changed to the LS (pattern P4) with W1×L2 as shown in the template T2 after the modification, enabling to reduce the filling time.

For example, when L2 is 400 nm, the pattern P4 can be filled with the imprint resist in 20 sec. In this manner, when the necessary throughput, the material for the resist 8A, and the process parameters are determined, it is possible to determine the DR with the maximum size with respect to the rectangular size of the pattern. This method can be applied to the rule or the like when generating a dummy pattern or the like.

Moreover, as explained in the DR determination in the template manufacturing, the processing bias in the processing process of the wafer 7 can also be assumed taking into account experience in the previous generation, experimental data when applying a new process, and the like. Therefore, the target pattern in the NIL is converted and the NIL and the template processing process are examined and evaluated based on the experience of the previous generation, the experimental data when applying a new process, and the like, enabling to reflect the effect of the wafer processing bias on the determination of the DR or the process parameters. Whereby, the circuit layout of the pattern can be generated based on the process parameters or the DR.

### (Step S220) <Generation of Design Data, DRC>

Generation of the design data is performed based on the DR determined at Step S210. Moreover, the DRC is performed on the generated design data, whereby a design failure due to a device operation and device characteristics is extracted to modify the design data. These processes are repeated to generate the design data that satisfies the DR and the spec with respect to the device operation and the device characteristics.

### (Step S230) <Generation of Template Data>

After generating the new design data at Step S220, this design data is subjected to a wafer processing bias correction c1, a processing bias correction (wafer NIL processing bias correction) c2 for the finished dimension due to the NIL, and a template processing bias correction c3. Thereafter, the design data after the template processing bias correction c3 is subjected to a black-and-white reversal process and a mirror reversal process to generate the template data (EB data).

The template processing bias correction c3 in this example is a process of correcting the template processing bias 23A that occurs in the template manufacturing process. The wafer NIL processing bias correction c2 is a process of correcting the wafer NIL processing bias 24 that occurs in the wafer NIL process. The wafer processing bias correction c1 is a process of correcting the wafer processing bias 25 that occurs in the process of processing the processing target film on the wafer from above a resist mask formed in the NIL process using the template. Each correction is performed to eliminate the processing bias.

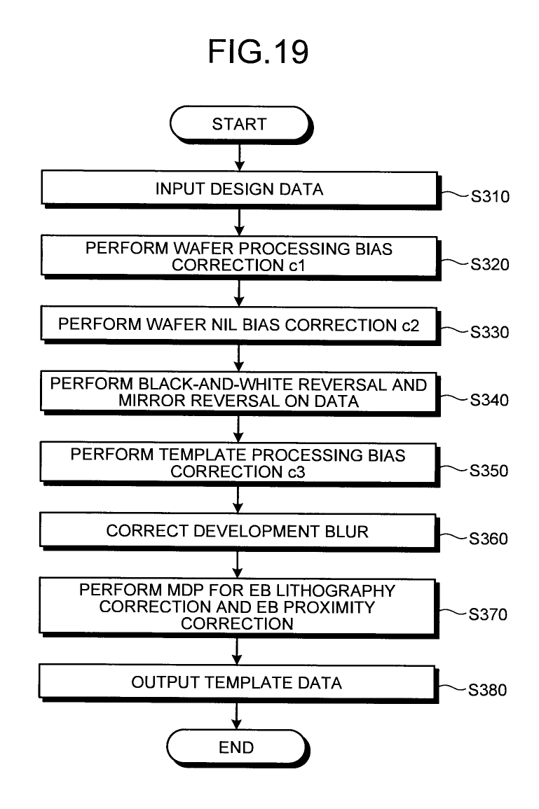

FIG. 19 is a flowchart illustrating the correction procedure of the template data. When the design data satisfying the design constraints due to the NIL is input (Step S310), the wafer processing bias correction c1 and the wafer NIL processing bias correction c2 are performed on the design data (Steps S320 and S330). Thereafter, the data is subjected to the black-and-white reversal process and the mirror reversal process (Step S340).

Moreover, the template processing bias correction c3 and a development blur correction are performed (Steps S350 and S360). At this time, the template processing bias correction c3 is performed based on the template processing bias 23A, and the development blur correction is performed based on the development blur 22.

Furthermore, the MDP for the EB lithography correction and an EB proximity correction (proximity correction of the EB lithography data) are performed (Step S370). At this time, the EB proximity correction is performed based on the EB proximity effect 21. The template data (template writing data D) is generated by performing the processes at Steps S320 to S370 and is output (Step S380).

### (Step S240) <Manufacturing of Template>

In the actual template writing, the deposited energy distribution is calculated by performing the proximity correction process, and a dose of beam is controlled for each writing position based on the deposited energy distribution. Whereby, the pattern formation can be performed as a desired template writing target. In the EB lithography, the effects of the PEB and the development after the EB lithography are superimposed and the final EB resist pattern is formed. Then, the HM and the Qz of the template are processed with the EB resist pattern as a mask material. Thereafter, the final template shape is measured. Whereby, it is possible to obtain the finished shape on which an effect of a microloading effect and a density difference effect when processing the template are reflected. Thereafter, a stripping process of the HM from the template is performed and the template is cleaned to complete the template.

### (Step S250) <Verification of Template>

It is verified and confirmed whether the performance of the template satisfies a desired dimension and shape specification. When the finished dimension and the finished shape of the template are within the specification (Yes at Step 250), this template is determined to pass (OK) and is supplied to the next process.

On the other hand, when the finished dimension and the finished shape of the template are out of the specification even if an EB lithography parameter is given (when a desired spec is not satisfied) (No at Step S250), the system control returns to Step S230. Then, modification of a template manufacturing parameter or the proximity correction process for the EB lithography data is performed to generate new EB lithography data, and the template is generated again. The processes at Steps S230 to S250 are repeated until the template is determined to pass, whereby the template satisfying a desired spec is manufactured.

When the finished dimension and the finished shape of the template are out of the specification even if the processes at Steps S230 to S250 are repeated (when the template satisfying a desired spec cannot be manufactured), the system control can return to Step S210 and change of the DR or the circuit layout can be performed. In this case, modification of the design data is performed and the processes from the writing data generation to the template manufacturing are performed again.

Then, it is verified whether the finished dimension and the finished shape of the template satisfy a desired dimension and shape specification. When the finished dimension and the finished shape of the template are out of the specification even if the EB lithography parameter is given (No at Step S250), the processes at Steps S230 to S250 are repeated. When the finished dimension and the finished shape of the template are out of the specification even if the processes at Steps S230 to S250 are repeated, the processes at Steps S210 to S250 and the processes at Steps S230 to S250 are repeated. The processes at Steps S210 to S250 and the processes at Steps S230 to S250 are repeated until the template is determined to pass, whereby the template satisfying a desired spec is manufactured.

### (Step S260) <Wafer NIL Process>

Thereafter, the NIL process is performed on the wafer 7 by using the template that is determined to pass to form the resist pattern on the wafer 7. Then, a dimension inspection and a defect inspection are performed on the post-NIL resist pattern on the wafer 7.

(Step S270) <Result Verification and Modification after NIL>

The dimension, the shape, and the defect of the post-NIL resist pattern are confirmed by the dimension inspection and the defect inspection on the post-NIL resist pattern. In other words, it is confirmed whether the post-NIL resist pattern is finished as desired. Then, the NIL condition (the discharge recipe and the filling time) is calculated based on the confirmation result of the post-NIL resist pattern. Specifically, the NIL condition is calculated by taking into account the effect of the based substrate, and the finished shape and the defect information of the template. Alternatively, the NIL condition can be set based on whether the post-NIL resist pattern is finished as a desired resist residual film thickness.

When the dimension, the shape, and the defect of the post-NIL resist pattern are within the specification (Yes at Step S270), this post-NIL resist pattern is determined to pass and is supplied to the next process. On the other hand, when the dimension, the shape, and the defect of the post-NIL resist pattern are not within the specification (No at Step S270), if the dimension can be modified by performing change of the NIL release material component, a dose change, a resist-residual-film change, and the like, the NIL process is performed again after these NIL process changes. Then, the dimension verification of the post-NIL resist pattern and the NIL process changes are repeatedly experimented until the dimension of the post-NIL resist pattern falls within a desired spec.

When the dimension of the post-NIL resist pattern is out of the specification (NG) even if these repeated experiments are performed (No at Step S270), the system control returns to Step S230. Then, change of the parameter of the processing bias by the imprint or change of the processing process parameter of the mask is performed to generate the EB lithography data again. Alternatively, the proximity correction process for the EB lithography data is changed to correct (absorb) the dimensional fluctuation by the imprint process and new EB lithography data is generated to manufacture the template again. The template satisfying a desired spec is manufactured by these repetitions. Then, the imprint process by using the manufactured template and the process of confirming the resist dimension and the like are repeated.

When it is difficult to form a desired post-NIL pattern even if the EB lithography data is generated again by returning to Step S230, the system control can return to Step S210. In this case, the DR or the circuit layout is changed to perform modification of the design data, and the writing data generation, the template manufacturing, and the NIL are performed again.

When the defect inspection is failed, i.e., (1) when the non-fill failure due to the Non-Fill occurs or (2) when the release defect occurs, data modification and experimental verification are performed in the flow described below so that the defect inspection satisfies the spec.

In the case of (1), it is examined whether the non-fill failure can be solved by optimizing the discharge recipe of the resist. Specifically, discharge recipe on which the performance and the shape of the template are reflected is generated, and the NIL and the defect inspection are performed again. When the defects are not reduced, the filling time is given within the allowable range as a parameter and a defect evaluation is performed. When the defect is not improved by the change of these NIL process parameters (No at Step S270), the system control returns to Step S210 or Step S230 and a pattern division or a dummy pattern generation is performed within the allowable range in a device/process integration. Then, the template manufacturing, the NIL, and the defect evaluation are performed again. The post-NIL pattern satisfying a desired defect spec is formed by repeating these processes.

Moreover, in the case of (2), when the release defect can be solved by changing the NIL process such as revision of the release material component, the NIL process is changed. On the other hand, when the release defect cannot be solved by changing the NIL process, the system control returns to Step S210 or Step S230. Then, the release force is reduced by generating a dummy pattern near the release defect generated portion or by performing the pattern modification, the circuit layout modification, or the like within the range allowable in the device/process integration. Whereby, reduction of the release defects is performed. When verifying the release defect, the reduction of the release defects is confirmed in the order of modification of the EB lithography data, the template manufacturing, the wafer NIL, and the defect evaluation.

### (Step S280) <Processing of Processing Target Film 9>

The processing target film 9 is etched with the post-NIL resist pattern formed in the NIL as a mask. At this time, when the processing target film 9 is a stacked film, a stack processing process is performed. When etching the processing target film 9, a resist-residual-film breakthrough etching is performed.

### (Step S290) <Confirmation of Processed Dimension>

After the processing target film 9 on the wafer 7 is patterned, the final processed dimension (pattern dimension) of the processing target film 9 is confirmed. The final processed dimension of the processing target film 9 is a wafer processed dimension. At this time, the wafer processing bias and a wafer processed shape are also confirmed. When the wafer processed dimension is within the specification (Yes at Step S290), the flow of determining at least one of the circuit layout, the template data, the DR, and the process parameters ends.

On the other hand, when the wafer processed dimension is out of the specification (when the dimension spec is NG) or is NG in the device/process integration (No at Step S290), the system control returns to Step S230. Then, the processing bias amount is modified, and the content of the MDP process is modified to generate the EB lithography data again. Then, the template manufacturing, the NIL, the wafer processing, and confirmation of the final dimension are performed.

When the wafer processed dimension is out of the specification or is NG in the device/process integration even if these processes are performed, the system control can return to Step S210 and modification of the circuit layout, the DR change, or the like can be performed. In this case, modification of the design data is performed, and the writing data generation, the template manufacturing, the NIL, the wafer processing, and confirmation of the final dimension are performed again.

In the procedure explained in FIG. 12, the dimension, the shape, and the defect are confirmed individually in each process of the template manufacturing, the NIL, and the wafer processing; however, the confirmation of the dimension, the shape, and the defect is not limited to be performed in the individual process and can be performed between the processes. For example, if the dimension or the like is NG after the wafer processing, it is applicable to confirm the dimension and the shape of the template manufactured based on the EB lithography data after the MDP in the case where at least one of the process parameters, the processing bias, the circuit layout, and the DR is changed and confirm the dimension, the defect, and the like after the NIL. Whereby, even when the template finishing or the imprint finishing is affected by change of the processing process or change performed for modifying a failure after processing, the effect of the change can be confirmed by interposing the verification process between the processes.

In this manner, it is possible to determine at least one of the circuit layout, the template data, the DR, and the process parameters when manufacturing a semiconductor device by using the NIL by performing the flow shown in FIG. 12 explained in the present embodiment once or more. Whereby, the template writing data and the process condition for performing the optimum NIL can be provided while making the design constraints constrained in each process clear.

Various conditions (NIL information) for the NIL are determined, for example, for each layer of the wafer process. When the condition for the NIL in each layer is determined, the NIL process, the etching processing, and the like are performed on the wafer by using each condition, whereby a device such as a semiconductor device is manufactured.

In this manner, the pattern data such as the template writing data D and the template data is changed based on the EB proximity effect 21, the development blur 22, the template processing bias 23A, the wafer NIL processing bias 24, and the wafer processing bias 25, so that a desired pattern formation can be performed by using the NIL.

When performing the flow explained in FIG. 12, a simulation can be used. Specifically, when determining at least one of the circuit layout, the template data, the DR, and the process parameters, it is applicable to estimate each of the template shape, the resist pattern shape, and the wafer processed shape when the resist pattern is used as a mask by simulation.

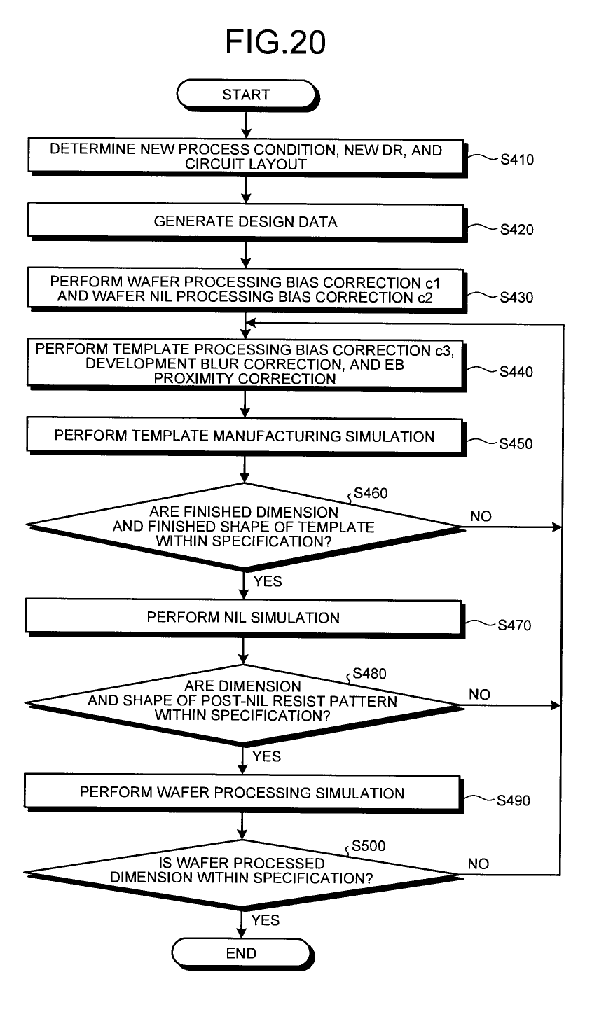

FIG. 20 is a flowchart illustrating a procedure for determining the pattern or the process condition used in the NIL in the first embodiment by using a simulation. In this example, explanation of the processes similar to the processes explained in FIG. 11, FIG. 12, and FIG. 19 are omitted, and the processes different from FIG. 11, FIG. 12, and FIG. 19 are mainly explained.

A new process condition, a new DR, and the circuit layout are temporarily determined (Step S410), and generation of the design data is performed based on the new DR (Step S420). Then, the wafer processing bias correction c1 and the wafer NIL processing bias correction c2 are performed on the design data (Step S430). Moreover, the template processing bias correction c3, the development blur correction, and the EB proximity correction are performed (Step S440).

Thereafter, the template manufacturing process (such as writing and processing) is simulated (Step S450). Then, it is confirmed whether the finished dimension and the finished shape of the template are within the specification (Step S460). When the finished dimension and the finished shape of the template are within the specification (when a desired dimension and shape specification is satisfied) (Yes at Step S460), this template is determined to pass and is supplied to the next process.

Next, the dimension and the shape of the post-NIL resist pattern are simulated (NIL simulation) by using the data of the template derived by the simulation (Step S470). Then, it is confirmed whether the dimension and the shape of the post-NIL resist pattern are within the specification (Step S480). When the dimension and the shape of the post-NIL resist pattern are within the specification (Yes at Step S480), this post-NIL resist pattern is determined to pass and is supplied to the next process.

Thereafter, the dimension and the shape of the wafer processed pattern formed on the wafer are simulated (wafer processing simulation) by using the post-NIL resist pattern derived by the simulation (Step S490). Then, it is confirmed whether the wafer processed dimension of the wafer processed pattern is within the specification (Step S500).

In the process at Step S460, when the finished dimension and the finished shape of the template are out of the specification (No at Step S460), the system control returns to Step S440. Then, modification of the template manufacturing parameter or the like is performed, and the template processing bias correction c3, the development blur correction, and the EB proximity correction are performed, to generate new EB lithography data, and the template manufacturing process is simulated again. The processes at Steps S440 to S460 are repeated until the template is determined to pass, whereby the template satisfying a desired spec is manufactured.

When the finished dimension and the finished shape of the template do not fall within the specification even if the processes at Steps S440 to S460 are repeated (No at Step S460), the system control can return to Step S410 and change of the DR or the circuit layout can be performed. In this case, modification of the design data is performed to perform the simulation from the writing data generation to the template manufacturing again.

The processes at Steps S410 to S460 and the processes at Steps S440 to S460 are repeated until the template is determined to pass, whereby the template satisfying a desired spec is manufactured.

Moreover, when the dimension and the shape of the post-NIL resist pattern are out of the specification (No at Step S480), the system control returns to Step S440. Then, modification of the template manufacturing parameter or the like is performed, and the template processing bias correction c3 and the like are performed, to generate new EB lithography data, and the template manufacturing process is simulated again. The processes at Steps S440 to S480 are repeated until the post-NIL resist pattern is determined to pass, whereby the post-NIL resist pattern satisfying a desired spec is manufactured.

When the dimension and the shape of the post-NIL resist pattern do not fall within the specification even if the processes at Steps S440 to S480 are repeated (No at Step S480), the system control can return to Step S410 and change of the DR or the circuit layout can be performed. In this case, modification of the design data is performed to perform the simulation from the writing data generation to the template manufacturing again.

The processes at Steps S410 to S480 and the processes at Steps S440 to S480 are repeated until the post-NIL resist pattern is determined to pass, whereby the post-NIL resist pattern satisfying a desired spec is manufactured.

Furthermore, when the wafer processed dimension of the wafer processed pattern is out of the specification (No at Step S500), the system control returns to Step S440. Then, modification of the template manufacturing parameter or the like is performed, and the template processing bias correction c3 and the like are performed, to generate new EB lithography data, and the template manufacturing process is simulated again. The processes at Steps S440 to S500 are repeated until the wafer processed pattern is determined to pass, whereby the wafer processed pattern satisfying a desired spec is manufactured.

When the wafer processed dimension does not fall within the specification even if the processes at Steps S440 to S500 are repeated (No at Step S500), the system control can return to Step S430. In this case, the processing bias amount or the like is modified, and the wafer processing bias correction c1, the wafer NIL processing bias correction c2, and the like are performed, to generate new EB lithography data, and the manufacturing process of the wafer processed pattern is simulated again. The processes at Steps S430 to S500 are repeated until the wafer processed pattern is determined to pass, whereby the wafer processed pattern satisfying a desired spec is manufactured.

When the wafer processed dimension does not fall within the specification even if the processes at Steps S430 to S500 are repeated (No at Step S500), the system control can return to Step S410 and change of the DR or the circuit layout can be performed. In this case, modification of the design data is performed to perform the simulation from the writing data generation to the template manufacturing again.

The processes at Steps S410 to S500, the processes at Steps S430 to S500, and the processes at Steps S440 to S500 are repeated until the wafer processed pattern is determined to pass, whereby the wafer processed pattern satisfying a desired spec is manufactured.

Consequently, it is possible to determine at least one of the circuit layout, the template data, the design rule, and the process parameters.

In the simulation at Steps S470 to S480 in FIG. 20, the non-fill failure in the NIL process can be calculated by a filling simulation. It is applicable to recognize the defect by setting such that when the volume of a space of the template in which resin is not filled in a predetermined filling time in the NIL process exceeds a predetermined value, it is output as the defect. In order to eliminate the detected defect or cause the number of the detected defects to be equal to or lower than the allowable number of the defects, the NIL process parameters at Step S470 is changed and the simulation is performed, and this simulation and determination process is repeated until a post-NIL defect is determined to be OK. When the predetermined number of the defects cannot be achieved even if the process parameters are changed, the system control can return to Step S410 and change of the DR or the circuit layout can be performed. In this case, modification of the design data is performed and the simulation of the template generation and the imprint process is performed again. The processes at Steps S410 to S480 are repeated until the number of the defects is determined to pass, whereby the post-NIL pattern satisfying a desired spec can be formed (simulated).

Moreover, it is applicable to optimize at least one of the circuit layout, the template data, the design rule, and the process parameters by using only a specific process out of the processes explained in FIG. 20. For example, it is applicable to optimize at least one of the circuit layout, the template data, the design rule, and the process parameters by using the processes from Steps S410 to S480.

Furthermore, it is applicable to substitute any of the respective processes in which the simulation explained in FIG. 20 is used with a process in which experimental data is used. For example, the shape finished data of the template is experimentally obtained by using an SEM or the like in advance, and this data is used as input data in the NIL simulation, thereby estimating the shape and the dimension of the post-NIL resist pattern. In this manner, the template pattern, the post-NIL resist pattern, the wafer processed pattern can be derived by combining the experiment or the simulation.

In this manner, according to the first embodiment, the finished shape of the design layout on the substrate is obtained in accordance with at least one of the filling information on the resist 8A, the release information on the releasing of the template, and the processing bias information, and when the finished shape does not satisfy a predetermined evaluation condition as a result of comparison of a desired pattern shape and the finished shape formed above the wafer, the pattern data used for forming the integrated circuit pattern is changed so that the finished shape satisfies the evaluation condition, so that a desired pattern formation using the NIL can be performed.

Moreover, because the number and the type of the dangerous patterns in the design layout are monitored, it is possible to set the optimum DR or process parameters with which the number of the dangerous patterns satisfies the evaluation condition.

### Second Embodiment

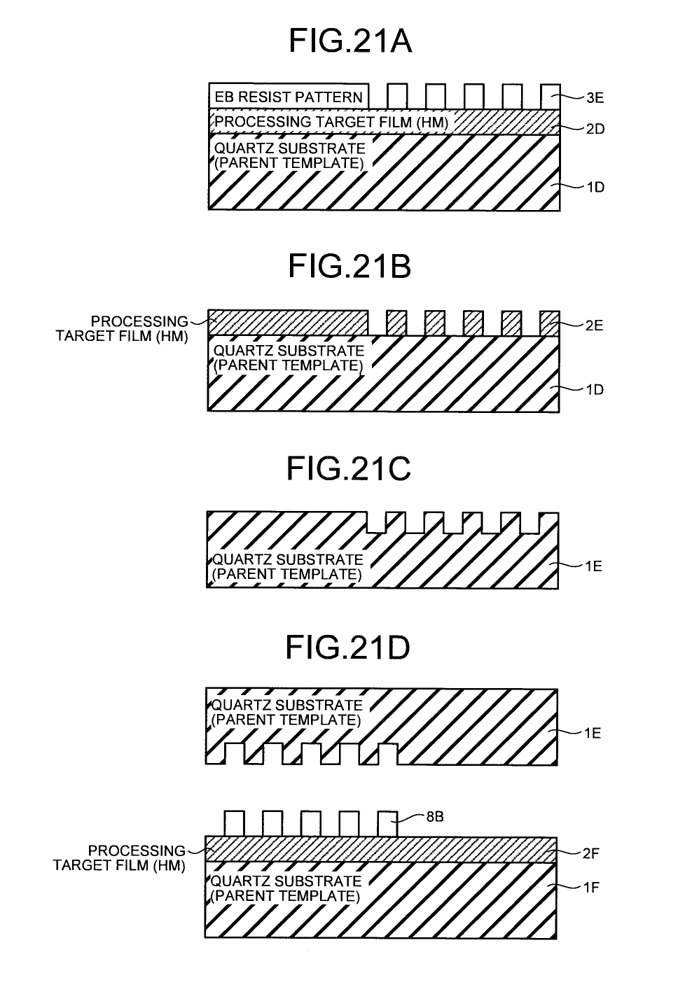

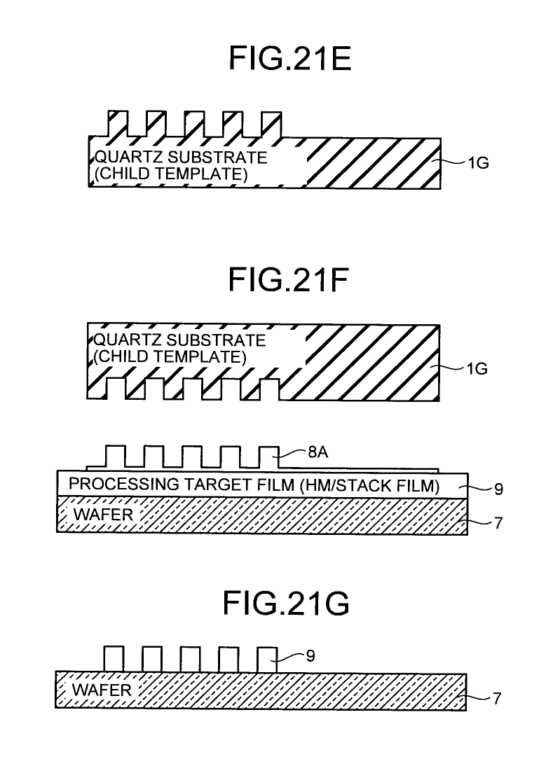

Next, the second embodiment is explained with reference to FIG. 21A to FIG. 27. In the second embodiment, a template manufacturing flow is performed in two stages by manufacturing a child template (daughter template) for the wafer imprint by using a parent template (master template). Specifically, the parent template to be a master for the child template is manufactured by the EB lithography. Then, the NIL is performed with the manufactured parent template as a substrate to manufacture (copy) the child template (Daughter template). When performing the pattern formation above the wafer, the child template is used.

The advantage of performing the pattern formation above the wafer by using the child template is that once the parent template is manufactured with high precision, the child template can be manufactured uniformly at low cost by the NIL technology. In the present embodiment, explanation is given for a case where the NIL to the child template by using the parent template and the NIL to the wafer by using the child template are verified by experiment and various conditions related to the NIL are set based thereon.

### (NIL Process Steps)

First, the NIL process steps according to the second embodiment are explained. A pattern forming method according to the second embodiment by using the NIL includes a parent template manufacturing process of manufacturing the parent template, a child template manufacturing process of manufacturing the child template, a wafer NIL process of forming a resist mask pattern on the processing target film by using the child template, an imprint apparatus, and the resist material, and an etching process (processing process) of processing the processing target film from above the resist mask formed by the imprint. Among them, the wafer NIL process and the etching process have the process procedure similar to the first embodiment, so that explanation thereof is omitted.

FIG. 21A to FIG. 21G are diagrams illustrating the template manufacturing process according to the second embodiment. The template manufacturing process includes the parent template manufacturing process and the child template manufacturing process. In manufacturing the parent template, as shown in FIG. 21A, a Qz blank substrate (quartz substrate 1D) used for manufacturing a photomask or the like is used. The quartz substrate 1D in this example is, for example, a 6025 blank to be the parent template. In the parent template manufacturing process, first, a processing target film 2D (processing target film for the parent template) to be the HM material is formed on the quartz substrate 1D, and the EB resist (not shown) is applied on the processing target film (hard mask) 2D.

Then, the design data is converted into a target design for the template writing by performing desired data processing on the design data, and the electron beam (EB) lithography is performed on the EB resist by an EB lithography apparatus by using the converted data.

After performing the EB lithography, an EB resist pattern 3E is formed through the developing process. Thereafter, the processing target film 2D on the quartz substrate 1D is etched with the EB resist pattern 3E as a mask material. Whereby, a patterned processing target film 2E is formed (FIG. 21B). For example, as the hard mask material on the Qz blank substrate, Cr, MoSi, or the like is used.

Thereafter, a resist residue is ashed, and then the quartz substrate 1D is cleaned and the quartz substrate 1D is etched with the patterned processing target film 2E as a mask. Whereby, a patterned quartz substrate 1E is formed (FIG. 21C).

An etching depth of the quartz substrate 1E is set so that the resist pattern with a height necessary for manufacturing the child template by the NIL is formed. In other words, a Qz digging depth of the child template is set so that the resist height required for the imprint resist when performing the wafer NIL by using the child template can be provided. Then, the depth of the parent template is determined in accordance with a process integration of Qz processing and HM processing of this child template so that the Qz digging depth of this child template can be obtained. Moreover, a side wall angle after etching the quartz substrate 1D is preferably close to 90° with respect to the bottom surface; however, the side wall can be tapered depending on the constraints in the imprint.

After forming the quartz substrate 1E, the processing target film 2E is removed and the quartz substrate 1E is cleaned, and the quartz substrate 1E that is a 6025 blank is divided into four pieces to complete the parent template. Whether to divide the quartz substrate 1E into four pieces is determined depending on a specification of a nanoimprint apparatus that manufactures the child template, and the quartz substrate 1E with the blank size can be used without performing the dicing process.

Next, a manufacturing flow of the child template by using the parent template manufactured by the above manufacturing flow is explained with reference to FIG. 21D and FIG. 21E. The child template is patterned by an imprint apparatus by using the parent template.

As shown in FIG. 21D, the HM and the Qz substrate for processing can be similar to those in the manufacturing flow of the parent template; however, because the child template is patterned by the NIL, the discharge recipe for applying an NIL resist 8B can be generated and the NIL can be performed. The flow of generating the discharge recipe is similar to the flow of generating the discharge recipe in the above wafer NIL, so that explanation thereof is omitted.

The design data referenced to generate the discharge recipe is the pattern that is patterned in the child template manufacturing process, so that the data needs to reflect the finished shape of the parent template. The design data can be generated by a data processing flow by the MDP, or the result (such as SEM observation) obtained by observing the performance of the parent template can be used as the design data. Information referred to for the discharge recipe is not limited to a plane design that is obtained by performing the MDP process on the dimension, and it is applicable to refer to information on the shape and the performance such as a taper angle, a digging depth of the template (the parent template and the child template), and the defect information. Whereby, the discharge recipe further corresponding to the reality can be generated.

An appropriate imprint resist pattern can be formed above the child template substrate by performing the NIL using the discharge recipe that is appropriately generated and an imprint process condition. In the case of the child template, because the pattern of the child template is formed by the NIL different from the parent template, the blur or the like by the developing process does not occur.

In manufacturing the child template, a Qz blank substrate (quartz substrate 1F) used for manufacturing a photomask or the like is used. The quartz substrate 1F in this example is, for example, a 6025 blank to be the child template. In the child template manufacturing, first, a processing target film 2F (processing target film for the child template) to be the HM material is formed on the quartz substrate 1F, and the photo-curable resist (wafer NIL resist) 8B is applied on the processing target film 2F (hard mask).

The resist 8B is irradiated with light in a state where the quartz substrate 1E that is the parent template is pressed against the resist 8A to be patterned. Thereafter, the quartz substrate 1E that is the parent template is separated from the quartz substrate 1F that is the child template (releasing) (FIG. 21D). After removing a resist residual film (thin film remaining on the lower portion of the resist pattern 8B) after the releasing, the processing target film 2F is etched with the patterned resist 8B as a mask, whereby the processing target film 2F is patterned.

Thereafter, a resist residue is ashed, and then the quartz substrate 1F is cleaned and the quartz substrate 1F is etched with the patterned processing target film 2F as a mask. Whereby, a patterned quartz substrate 1G is formed (FIG. 21E). A digging depth of the quartz substrate 1G in this example is set so that the resist pattern height necessary in the wafer NIL is formed.

Thereafter, the patterning is performed on the substrate such as the wafer 7 by using the quartz substrate 1G (child template). The wafer 7 in this example is a process substrate (such as a silicon substrate) for transferring the pattern formed on the quartz substrate 1G by the imprint.

The processing target film 9 (processing target film for the wafer) (HM/Stack film) to be the hard mask material is stacked on the upper surface of the wafer 7. The photo-curable resist (wafer NIL resist) 8A is applied on the processing target film 9 of the wafer 7. Then, the resist 8A is irradiated with light in a state where the quartz substrate 1G is pressed against the resist 8A to be patterned. Thereafter, the quartz substrate 1G is separated from the wafer 7 (FIG. 21F). Then, the processing target film 9 is etched with the patterned resist 8A as a mask, whereby the processing target film 9 is patterned (FIG. 21G).

### (Dimensional Fluctuation Factors in NIL According to Second Embodiment)

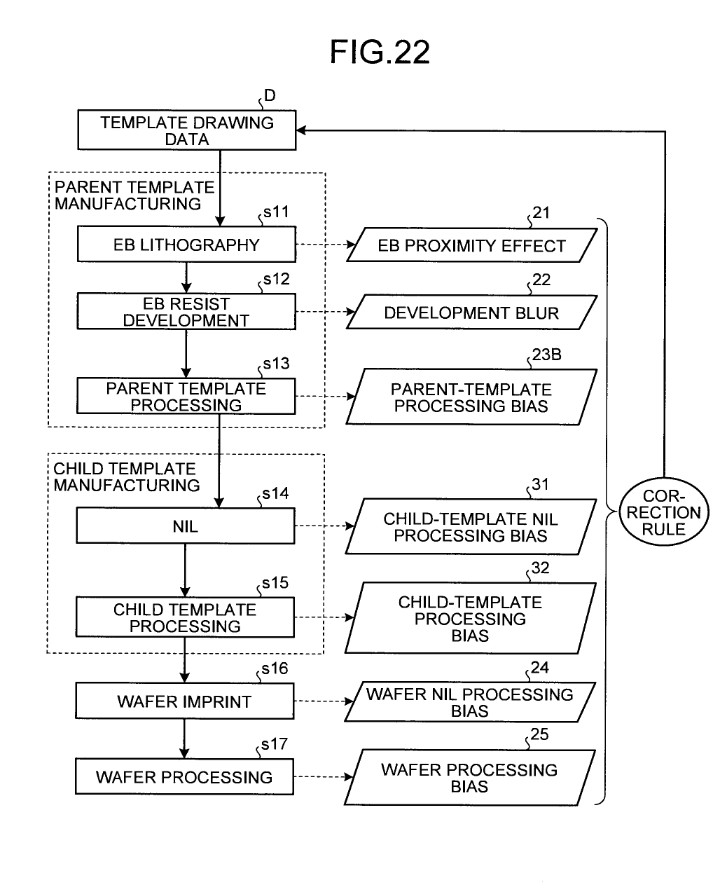

Next, a determination method of the NIL information according to the present embodiment is explained. FIG. 22 is a diagram for explaining processing bias factors that contribute to the dimensional fluctuation in the NIL in the second embodiment and the proximity effect. Among the processing bias factors shown in FIG. 22, the processing bias factors similar to the processing bias factors shown in FIG. 11 are given the same reference numerals. The parent template manufacturing process, the wafer NIL process, and the processing process of the processing target film in the present embodiment are similar to the first embodiment; however, in the present embodiment, the processing bias in the child template manufacturing process needs to be considered in addition to these processes.

A pattern transfer is performed on the child template by the NIL process, so that the NIL information needs to be designed by taking in the processing bias by the NIL process and the processing bias by the child template while taking into account that the child template pattern is black-and-white reversed with respect to the parent template pattern. In other words, the imprint processing bias and the processing bias of the child template need to be further added to the processing biases explained in the first embodiment to perform the MDP on the design data.

The EB lithography data that is the template data generated by performing the MDP process on the design data is generated as the template writing data D for the parent template in advance. In the template manufacturing, the EB lithography (s11) is performed to write the pattern corresponding to the template writing data D above the Qz blank substrate.

Thereafter, in the EB lithography, the energy distribution (latent image distribution) deposited in the EB resist by the EB lithography becomes the pattern of the EB resist 3B through the PEB process and the EB resist developing process (s12). Then, the HM (processing target film 2A) is processed and patterned, and parent template processing (s13) is performed by processing the Qz blank substrate with the processing target film 2B after patterning as a mask. Then, the parent template is completed by stripping the HM. The template writing data D is generated in advance following a correction rule in which the proximity effect (EB proximity effect 21) in the EB lithography, the development blur 22 in the EB developing process, and a parent-template processing bias 23B by performing a processing process on the parent template in the parent template manufacturing processes (s11 to s13) are all considered.

Moreover, the child template is patterned above the Qz blank substrate by the NIL process (s14) using the parent template. Thereafter, the HM (processing target film 2F) is processed and patterned, and child template processing (s15) is performed by processing the Qz blank substrate with the processing target film 2F after patterning as a mask. Then, the child template is completed by stripping the HM. The template writing data D is generated in advance following a correction rule in which the processing bias (child-template NIL processing bias 31) that occurs by the NIL from the parent template to the child template and a child-template processing bias 32 by performing a processing process on the child template in the child template manufacturing processes (s14 and s15) are all considered.

Thereafter, the wafer imprint (s16) is performed on the wafer 7 by using the child template that is finished as desired to form the imprint resist pattern. The processing target film 9 is etched with this imprint resist pattern as the HM, whereby formation of a processed pattern (wafer processing) (s17) to the wafer 7 is performed. The template writing data D is generated in advance following a correction rule in which the processing bias (wafer NIL processing bias 24) by the NIL and the processing bias (wafer processing bias 25) of the processing target film 9 in the wafer patterning processes (s16 and s17) are considered. The etching of the processing target film 9 can be a processing process by the stacked HM; however, a case is explained in which the wafer processing bias 25 in this example is the processing bias to the final dimension.

In this manner, a desired processed pattern cannot be obtained unless the processing bias and the proximity effect in the template manufacturing and the processing bias in the wafer patterning process are corrected with respect to the design data by performing the MDP process. In other words, the template writing data D needs to be corrected in accordance with a correction rule based on the EB proximity effect 21, the development blur 22, the parent-template processing bias 23B, the wafer NIL processing bias 24, the wafer processing bias 25, the child-template NIL processing bias 31, and the child-template processing bias 32.

Moreover, because the template writing data D needs to be generated in the form of satisfying all of the circuit pattern in each process, the constraint condition to the layout, and the required spec, it is difficult to construct a device manufacturing process that can obtain sufficient yield unless the DR, the circuit layout, and the process parameters that cover these constraint condition and required spec are found. Therefore, the present embodiment performs generation of the template writing data D and determination of the DR and the process parameters with which sufficient yield can be obtained, by using a flow explained below.

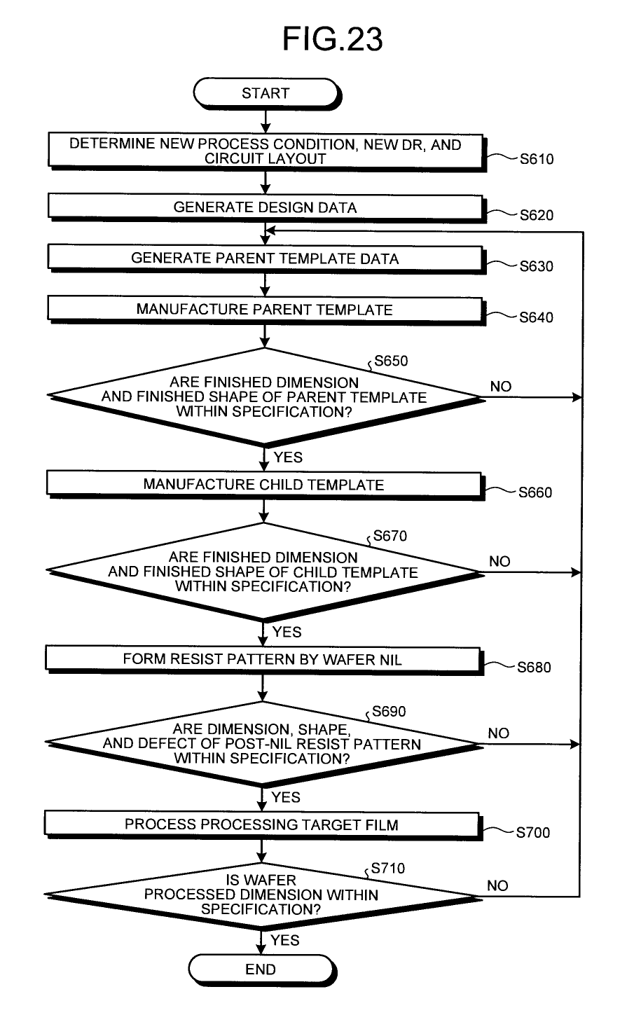

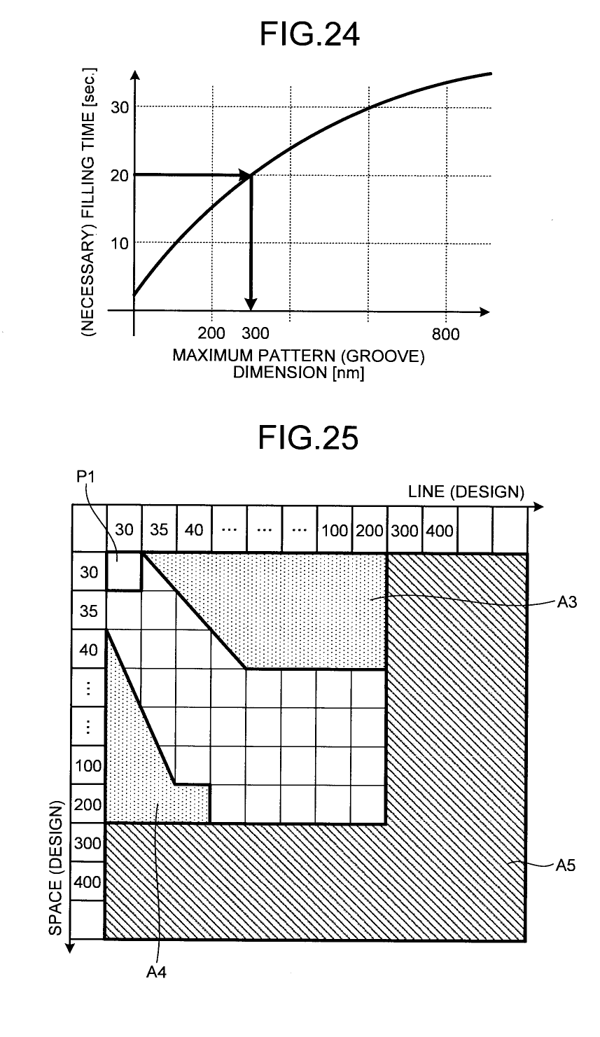

FIG. 23 is a flowchart illustrating a procedure for determining the pattern or the process condition used in the NIL in the second embodiment. FIG. 23 illustrates the flow for determining at least one of the circuit layout, the template data, the DR, and the process parameters when manufacturing a semiconductor device by using the NIL. Among the processes shown in FIG. 23, explanation for the processes similar to the processes shown in FIG. 12 is omitted. In the second embodiment, the design constraints (DR) and the processing bias associated with the child template generation are further added, which is different from the first embodiment.

### (Step S610) <Determination of DR>

The pattern used in the NIL is generated, for example, by shrinking the existing pattern by using data obtained by performing compaction on previous-generation design data as an example. Specifically, a new process condition, a new DR, and the circuit layout are temporarily determined by simulation or experiment in which the process condition and the NIL condition used in the next generation are taken into account. At this time, the DR based on the simulation or experimental data related to the template manufacturing process is also taken.

In the present embodiment, the DR is set in advance, with which pattern designing is performed in a state where the constraints on the child template by the NIL are added in addition to the constraints on the parent template generated by the EB lithography. FIG. 24 is a diagram illustrating a relationship between a pattern size (space dimension) and the filling time of the imprint resist. In the graph shown in FIG. 24, a horizontal axis indicates a maximum pattern (groove) of the pattern size and a vertical axis indicates the filling time necessary for the filling of the imprint resist.

For example, when there is the relationship as shown in FIG. 24, if constraints exist in which the filling time in one shot needs to be within 20 seconds in view of the throughput, “template groove width≦300 nm or lower” is set as the design constraints in the imprint process. For easy understanding although somewhat lacking in accuracy, constraints in which throughput constraints in the NIL process when generating the child template and the wafer NIL process using the child template are further added to the DR in FIG. 14 (EB lithography constraints+design constraints by template processing bias) in the first embodiment becomes the DR shown in FIG. 25.

FIG. 25 is a diagram illustrating a relationship between the finished pattern dimension after processing the template and the pattern dimension that cannot be formed on the template in the NIL according to the second embodiment. In the similar manner to FIG. 14, FIG. 25 illustrates a determination result indicating whether the pattern after processing a one-dimensional LS pattern is finished as a desired spec.

An area A5 shown in FIG. 25 is a violation design area defined by the throughput constraints on the imprint. Therefore, the constraints in which the prohibited areas that are the areas A3, A4, and A5 are added to the one-dimensional LS (line & space) are imposed to designing. The constraints are imposed on both of the space and the line because the patterns of the parent template and the child template are black-and-white (concave-and-convex) reversed. For other processing biases due to the imprint and the processing, the design constraints similar to the first embodiment are added, so that explanation thereof is omitted. In the present embodiment, because the processing bias for the child template manufacturing process is further added, the constraints to designing are higher than the first embodiment.

Moreover, for the Hot Spot on the circuit layout due to the process, the dangerous pattern is extracted by the releasability examination experiment, the releasability evaluation simulation, a filling failure examination experiment, a filling simulation, or the like of the circuit layout in the similar manner to the first embodiment. The layout modification, the process change and improvement, and the like are performed if necessary.

### (Step S620) <Generation of Design Data, DRC>

Generation of the design data of the parent template is performed based on the DR determined at Step S610. Moreover, the DRC is performed on the generated design data, whereby the design failure due to a device operation and device characteristics is extracted to modify the design data. These processes are repeated to generate the design data that satisfies the DR and the spec with respect to the device operation and characteristics.

### (Step S630) <Generation of Parent Template Data>

After generating the new design data at Step s620, this design data is subjected to a wafer processing bias correction c11 according to the child template, a wafer NIL processing bias correction c12 according to the child template, a child-template processing bias correction c13 for correcting the processing bias when processing the child template, an NIL processing bias correction (NIL processing bias correction according to the parent template) c14 for correcting the NIL processing bias from the parent template to the child template, and a parent-template processing bias correction c15 according to the parent template. Whereby, the parent template data (EB data) (design data) is generated. When generating the parent template data, the proximity correction process for the EB lithography of the parent template can be performed by data (graphics) operation if necessary.

The parent-template processing bias correction c15 in this example is a process of correcting the processing bias that occurs in the parent template manufacturing process. The NIL processing bias correction c14 according to the parent template is a process of correcting the NIL processing bias that occurs in the NIL process (child template manufacturing process) using the parent template.

The wafer NIL processing bias correction c12 according to the child template is a process of correcting the NIL processing bias that occurs in the wafer NIL process using the child template. The child-template processing bias correction c13 is a process of correcting the processing bias that occurs in a process of processing the processing target film on the child template from above the resist mask formed in the NIL process using the parent template.

The wafer processing bias correction c11 is a process of correcting the processing bias that occurs in a process of processing the processing target film on the wafer from above the resist mask formed in the NIL process using the child template. Each correction is performed to eliminate the processing bias.

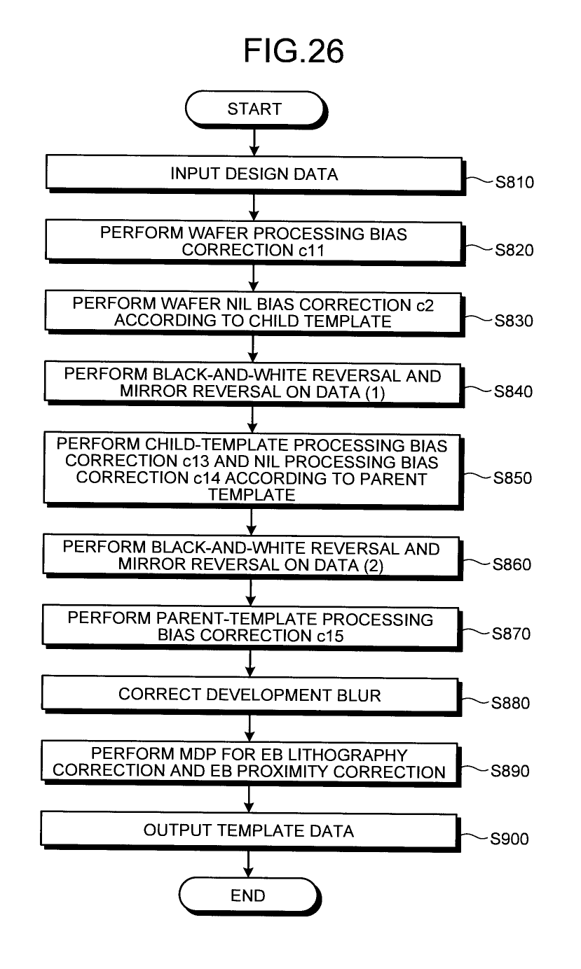

FIG. 26 is a flowchart illustrating the correction process procedure of the parent template data. When the design data of the parent template satisfying the design constraints due to the NIL is input (Step S810), the wafer processing bias correction c11 and the wafer NIL processing bias correction c12 according to the child template are performed on the design data (Steps S820 and S830). Thereafter, the data is subjected to the black-and-white reversal process and the mirror reversal process (Step S840).

Moreover, the child-template processing bias correction c13 and the NIL processing bias correction c14 according to the parent template are performed (Step S850). Thereafter, the black-and-white reversal process and the mirror reversal process are performed on the design data after correction (Step S860).

Thereafter, the parent-template processing bias correction c15 is performed (Step S870), and the development blur correction is performed (Step S880). The parent-template processing bias correction c15 is performed based on the parent-template processing bias 23B, and the development blur correction is performed based on the development blur 22.

Furthermore, the MDP for the EB lithography correction and the EB proximity correction (proximity correction of the EB lithography data) are performed (Step S890). At this time, the EB proximity correction is performed based on the EB proximity effect 21. The design data in which the MDP for the EB lithography correction and the EB proximity correction are completed becomes the parent template data. The template data (template writing data D) of the parent template is generated by performing the processes at Steps S820 to S890 and is output (Step S900).

### (Step S640) <Manufacturing of Parent Template>

Next, the parent template is manufactured by using the template data. In the actual template writing, the deposited energy distribution is calculated by performing the proximity correction process, and a dose of beam is controlled for each writing position based on the deposited energy distribution. Whereby, the pattern formation can be performed as a desired template writing target. In the EB lithography, the effects of the PEB and the development after the EB lithography are superimposed and the final EB resist pattern is formed. Then, the HM and the Qz of the template are processed with the EB resist pattern as a mask material. Thereafter, the final parent template shape is measured. Whereby, it is possible to obtain the finished shape on which the microloading effect and the density difference effect when processing the parent template are reflected. Thereafter, Cr is stripped from the parent template (stripping process of Cr) and the parent template is cleaned to complete the parent template.

### (Step S650) <Verification of Parent Template>

It is verified and confirmed whether the performance of the parent template satisfies a desired dimension and shape specification. When the finished dimension and the finished shape of the parent template are within the specification (Yes at Step 650), this parent template is determined to pass (OK) and is supplied to the next process.

On the other hand, when the finished dimension and the finished shape of the parent template are out of the specification even if the EB lithography parameter is given (when a desired spec is not satisfied) (No at Step S650), the system control returns to Step S630. Then, modification of a parent template manufacturing parameter or the proximity correction process for the EB lithography data is performed to generate new EB lithography data, and the parent template is generated again. The processes at Steps S630 to S650 are repeated until the parent template is determined to pass, whereby the parent template satisfying a desired spec is manufactured.

When the parent template that satisfies a desired spec cannot be manufactured even if the processes at Steps S630 to S650 are repeated, the system control can return to Step S610 and change of the DR or the circuit layout can be performed. In this case, modification of the design data is performed and the processes from the writing data generation to the template manufacturing are performed again.

### (Step S660) <Manufacturing of Child Template>

The child template is manufactured based on the parent template manufactured at Step S640. The child template is manufactured by transferring the pattern by the NIL using the parent template. Therefore, in the similar manner to the NIL to the wafer explained in the first embodiment, the resist discharge recipe on which concave-and-convex shape and distribution of the parent template is reflected is generated and the NIL is performed by discharging the resist material onto the Qz for the child template (HM is formed). The process for the child template can be the same as the parent template manufacturing process except for the patterning process. In the process for the child template, for example, Cr or MoSi is used as the HM. This is because the process can be used as a technology derived from a photomask process development.

### (Step S670) <Verification of Child Template>

Thereafter, it is verified whether the finished dimension and the finished shape of the child template manufactured at Step S660 satisfy a desired dimension and shape specification. When the finished dimension and the finished shape of the child template are within the specification (Yes at Step 670), this child template is determined to pass and is supplied to the next process.

On the other hand, when the finished dimension and the finished shape of the child template are out of the specification (when a desired spec is not satisfied) (No at Step S670), the parent template is manufactured again. In the parent template manufacturing, when a desired spec is not satisfied even if the EB lithography parameter is given, the system control returns to Step S630. Then, modification of the parent template manufacturing parameter or the proximity correction data process for the EB lithography data is performed to generate new EB lithography data, and the child template is generated again. The processes at Steps S630 to S670 are repeated until the child template is determined to pass, whereby the child template satisfying a desired spec is manufactured.

As the verification process of the child template, the performance can be verified in addition to the dimension. In this case, particularly, the defect due to the imprint is inspected to specify the location at which the defect occurs and is further sorted by each defect type. When the defect due to the NIL is the non-fill defect, (a) optimization of the discharge recipe or (b) modification of the circuit layout is performed. When the defect due to the NIL is the release defect, the defect is eliminated by (c) change or modification of the process condition or (d) change of the circuit layout is performed. As a countermeasure for such defects, change of the DR or change of the process condition such as the material can be performed. The child template of which defect spec becomes OK is supplied to the next process.

### (Step S680) <Wafer NIL Process>

Thereafter, the NIL process is performed on the wafer 7 by using the child template that is determined to pass to form the resist pattern on the wafer 7. Then, the dimension inspection and the defect inspection are performed on the resist pattern on the wafer 7.

(Step S690) <Result Verification and Modification after NIL>

The dimension, the shape, and the defect of the post-NIL resist pattern are confirmed by the dimension inspection and the defect inspection of the post-NIL resist pattern in the similar manner to the first embodiment. In other words, it is confirmed whether the post-NIL resist pattern is finished as desired. Then, the NIL condition (the discharge recipe and the filling time) is calculated based on the confirmation result of the post-NIL resist pattern. Specifically, the NIL condition is calculated by taking into account the effect of the based substrate, and the finished shape and the defect information of the child template. Alternatively, the NIL condition can be set based on whether the post-NIL resist pattern is finished as a desired resist residual film.

When the dimension, the shape, and the defect of the post-NIL resist pattern are within the specification (Yes at Step S690), this post-NIL resist pattern is determined to pass and is supplied to the next process. On the other hand, when the dimension, the shape, and the defect of the post-NIL resist pattern are not within the specification (No at Step S690), if the dimension can be modified by performing change of the NIL release material component, dimension adjustment of the parent template by changing an EB dose when manufacturing the parent template, the resist-residual-film change in the wafer NIL, and the like, the NIL process is performed again after these NIL process changes. The dimension adjustment of the resist pattern can be performed by the resist-residual-film change of the child template.

The dimension verification of the post-NIL resist pattern and the NIL process change are repeatedly experimented until the dimension of the post-NIL resist pattern falls within a desired spec. Specifically, an iteration experiment in which various process conditions are applied is performed until the dimension of the post-NIL resist pattern falls within a desired spec.

When the dimension of the post-NIL resist pattern is out of the specification (NG) even if these repeated experiments are performed (No at Step S690), the system control returns to Step S630. Then, change of the parameter of the processing bias by the imprint or change of the processing process parameter of the parent template is performed to generate the EB lithography data again. Alternatively, the proximity correction process for the EB lithography data is changed to correct the dimensional fluctuation by the imprint process and new EB lithography data is generated to manufacture the parent template and the child template again. The child template satisfying a desired spec is manufactured by these repetitions. Then, the wafer imprint process by using the manufactured child template and the process of confirming the resist dimension and the like are repeated.

When it is difficult to form a desired post-NIL pattern even if the EB lithography data is generated again by returning to Step S630, the system control can return to Step S610. In this case, the DR or the circuit layout is changed to perform modification of the design data, and the writing data generation, the template manufacturing, and the NIL are performed again.

When the defect inspection is failed, i.e., (1) when the non-fill failure occurs or (2) when the release defect occurs, data modification and experimental verification are performed in the flow described below so that the defect inspection result satisfies the spec.

In the case of (1), it is examined whether the non-fill failure can be solved by optimizing the discharge recipe of the resist. Specifically, the discharge recipe on which the performance and the shape of the child template are reflected is generated, and the wafer NIL and the defect inspection are performed again. When the defects are not reduced, the filling time is given within the allowable range as a parameter and the defect evaluation is performed. When the defect is not improved by the change of these wafer NIL process parameters (No at Step S690), the system control returns to Step S610 or Step S630 and the pattern division or the dummy pattern generation is performed within the allowable range in the device/process integration. Then, the parent template manufacturing, the child template manufacturing, the wafer NIL, and the defect evaluation are performed again. The post-wafer-NIL pattern satisfying a desired defect spec is formed by repeating these processes.

Moreover, in the case of (2), when the release defect can be solved by changing the NIL process such as revision of the release material component, the NIL process is changed. On the other hand, when the release defect cannot be solved by changing the NIL process, the system control returns to Step S610 or Step S630. Then, the release force is reduced by generating a dummy pattern near the release defect generated portion or by performing the pattern modification, the circuit layout modification, or the like within the range allowable in the device/process integration. Whereby, reduction of the release defects is performed. When verifying the release defect, the reduction of the release defects is confirmed in the order of modification of the EB lithography data, the parent template manufacturing, the parent template inspection, the child template manufacturing, the child template inspection, the wafer NIL, and the defect evaluation.

### (Step S700) <Processing of Processing Target Film 9>

The processing target film 9 is etched with the resist pattern formed in the NIL as a mask in the similar manner to the process in the first embodiment. At this time, when the processing target film 9 is a stacked film, the stack processing process is performed. When etching the processing target film 9, the resist-residual-film breakthrough etching is performed.

### (Step S710) <Confirmation of Processed Dimension>

Thereafter, the wafer processed dimension is confirmed and the wafer processing bias is checked. The processed dimension (final dimension) after processing the wafer is the wafer processed dimension. When the wafer processed dimension is within the specification (Yes at Step S710), the flow of determining at least one of the circuit layout, the template data, the DR, and the process parameters ends.

On the other hand, when the wafer processed dimension is out of the specification (when the dimension spec is NG), if the processed dimension that satisfies a desired spec can be obtained and a desired process margin can be ensured by providing the resist-residual-film film thickness or the processing condition in the wafer NIL process, it is possible to solve by the process condition change of only the wafer processing process. When it is impossible to solve in the wafer processing process (process margin is insufficient), modification of the wafer processing bias amount is performed by returning to Step S630 and the content of the MDP process is modified to generate the EB data. Then, each process is performed in the order of the parent template manufacturing, the parent template inspection, the child template manufacturing, the child template inspection, the wafer NIL, the resist pattern evaluation, the wafer processing, and the final dimension confirmation.

When the processed dimension is NG in this second final dimension confirmation, the system control can return to Step s610. In this case, modification of the design data is performed by performing the layout modification or the DR change. Then, each process is performed in the order of generation of the EB lithography data, the parent template manufacturing, the parent template inspection, the child template manufacturing, the child template inspection, the wafer NIL, the resist pattern evaluation, the wafer processing, and the processed dimension confirmation. In iteration of these processes, at least one of the circuit layout, the template data, the DR, and the process parameters can be optimized and modified.

In the procedure explained in FIG. 23, the dimension, the shape, and the defect are confirmed individually in each process of the parent template manufacturing, the child template manufacturing, the wafer NIL, and the wafer processing; however, the confirmation of the dimension, the shape, and the defect is not limited to be performed in the individual process and can be performed between the processes. For example, if the dimension or the like is NG after the wafer processing, it is applicable to confirm the dimension and the shape of the child template manufactured based on the EB lithography data after the MDP in the case where at least one of the process parameters, the processing bias, the circuit layout, and the DR is changed and confirm the dimension, the defect, and the like after the NIL. Whereby, even when the template finishing or the imprint finishing is affected by change of the processing process or change performed for modifying a failure after processing, the effect of the change can be confirmed by interposing the verification process between the processes.

In this manner, it is possible to determine at least one of the circuit layout, the template data, the DR, and the process parameters when manufacturing a semiconductor device by using the NIL by performing the flow shown in FIG. 23 explained in the present embodiment once or more. Whereby, the parent template writing data and the process condition for performing the optimum NIL can be provided while making the design constraints constrained in each process clear.

When performing the flow explained in FIG. 23, a simulation can be used. Specifically, when determining at least one of the circuit layout, the template data, the DR, and the process parameters, it is applicable to estimate each of the template shape, the resist pattern shape, the wafer processed shape when the resist pattern is used as a mask by simulation.

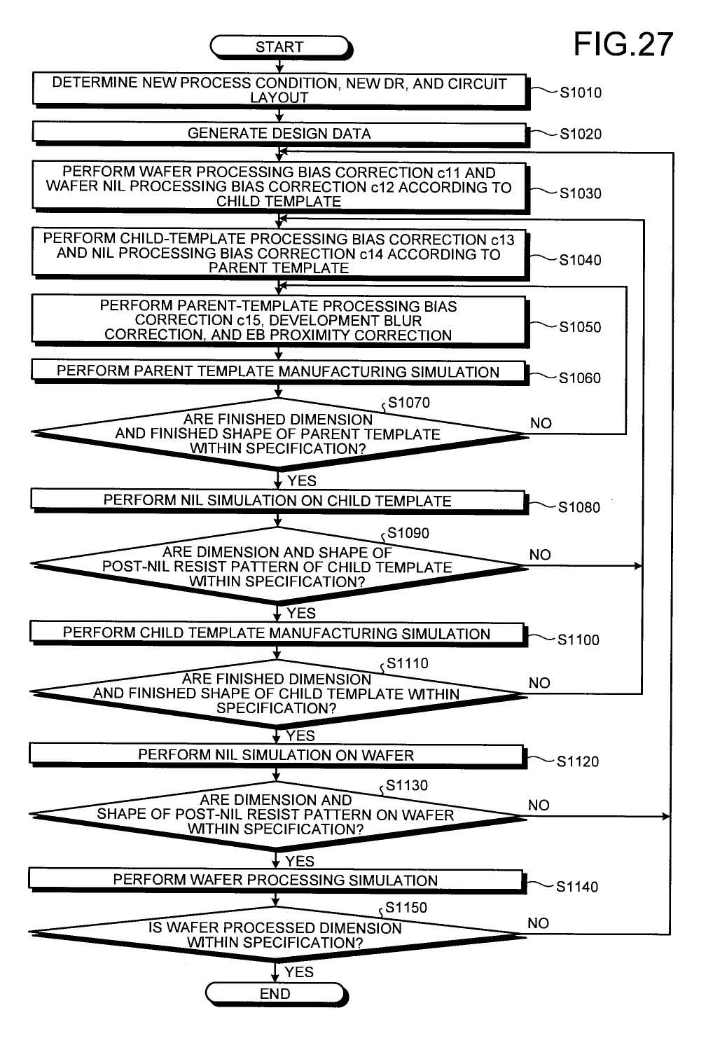

FIG. 27 is a flowchart illustrating a procedure for determining the pattern or the process condition used in the NIL in the second embodiment by using a simulation. In this example, explanation of the processes similar to the processes explained in FIG. 20, FIG. 22, FIG. 23, and FIG. 26 are omitted, and the processes different from FIG. 20, FIG. 22, FIG. 23, and FIG. 26 are mainly explained.

A new process condition, a new DR, and the circuit layout are temporarily determined (Step S1010), and generation of the design data is performed based on the new DR (Step S1020). Then, the wafer processing bias correction c11 and the wafer NIL processing bias correction c12 according to the child template are performed on the design data (Step S1030). Moreover, the child-template processing bias correction c13 and the NIL processing bias correction c14 according to the parent template are performed (Step S1040). Furthermore, the parent-template processing bias correction c15, the development blur correction, and the EB proximity correction are performed (Step S1050).

Thereafter, the parent template manufacturing process (such as writing and processing) is simulated (Step S1060). Then, it is confirmed whether the finished dimension and the finished shape of the parent template are within the specification (Step S1070). When the finished dimension and the finished shape of the parent template are within the specification (Yes at Step S1070), this parent template is determined to pass and is supplied to the next process.

Next, the NIL simulation is performed on the child template by using the data of the parent template derived by the simulation (Step S1080). Then, it is confirmed whether the dimension and the shape of the post-NIL resist pattern of the child template are within the specification (Step S1090). When the dimension and the shape of the post-NIL resist pattern are within the specification (Yes at Step S1090), the post-NIL resist pattern of this child template is determined to pass and is supplied to the next process.

Thereafter, the child template manufacturing process is simulated by using the post-NIL resist pattern of the child template derived by the simulation (Step S1100). Then, it is confirmed whether the finished dimension and the finished shape of the child template are within the specification (Step S1110). When the finished dimension and the finished shape of the child template are within the specification (Yes at Step S1110), this child template is determined to pass and is supplied to the next process.

Next, the dimension and the shape of the post-NIL resist pattern formed on the wafer are simulated (NIL simulation) by using the data of the child template derived by the simulation (Step S1120). Then, it is confirmed whether the dimension and the shape of the post-NIL resist pattern on the wafer are within the specification (Step S1130). When the dimension and the shape of the post-NIL resist pattern on the wafer are within the specification (Yes at Step S1130), this post-NIL resist pattern is determined to pass and is supplied to the next process.

Thereafter, a wafer-processing simulation is performed for the dimension and the shape of the wafer processed pattern formed on the wafer by using the post-NIL resist pattern derived by the simulation (Step S1140). Then, it is confirmed whether the wafer processed dimension of the wafer processed pattern is within the specification (Step S1150).

In each process at Step S1070, Step S1090, Step S1110, Step S1130, and Step S1150, when the parent template, the post-NIL resist pattern of the child template, the child template, the post-NIL resist pattern on the wafer, and the wafer processed pattern are out of the specification, the processes at Steps S1010 to S1150 are repeated by the processes similar to the processes explained in FIG. 20, FIG. 22, FIG. 23, and FIG. 26.

Specifically, when the parent template does not satisfy a desired dimension and shape specification, the system control returns to Step S1050 or Step S1010. When the post-NIL resist pattern of the child template does not satisfy a desired dimension and shape specification, the system control returns to Step S1040 or Step S1010. When the child template does not satisfy a desired dimension and shape specification, the system control returns to Step S1040 or Step S1010.

Moreover, when the post-NIL resist pattern on the wafer does not satisfy a desired dimension and shape specification, the system control returns to Step S1030 or Step S1010. When the wafer processed pattern does not satisfy a desired dimension and shape specification, the system control returns to Step S1030 or Step S1010.

Consequently, the wafer processed pattern that satisfies a desired spec is manufactured. Moreover, it is possible to determine at least one of the circuit layout, the template data, the design rule, and the process parameters.

The parent template pattern, the post-NIL resist pattern of the child template, the child template pattern, the post-NIL resist pattern on the wafer, and the wafer processed pattern can be derived by combining the experiment and the simulation.

According to the second embodiment, because the pattern data such as the template writing data D is changed based on the child-template NIL processing bias 31 and the child-template processing bias 32, a desired pattern formation can be performed even by the NIL using the child template.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of generating a pattern comprising:
preparing a design pattern of a pattern above substrate formed by performing an imprint process using a template on a substrate;
obtaining the pattern above substrate by performing a process for forming the pattern above substrate by simulation or experiment based on the design pattern;
comparing the design pattern with obtained pattern above substrate and determining whether a comparison result satisfies a predetermined condition; and
employing the design pattern when the comparison result satisfies the predetermined condition and correcting the design pattern to satisfy the predetermined condition when the comparison result does not satisfy the predetermined condition.

2. The method according to claim 1, wherein the obtaining the pattern above substrate includes obtaining the pattern above substrate based on at least one of filling information on a filling process of a resist material to be filled between the template and the substrate when performing the imprint process, release information on a releasing process of the template from the substrate performed when performing the imprint process, and processing bias information on a processing bias when processing the substrate from above a resist mask formed by using the imprint process.

3. The method according to claim 2, wherein the filling information is information on a process that is affected by a pattern layout of the design pattern.

4. The method according to claim 3, wherein the filling information is a filling process parameter that affects a dimensional difference between a pattern of the template and a pattern of filled resist material.

5. The method according to claim 4, wherein the filling information includes a filling time required for the template to be filled with the resist material after bringing the resist material applied on the substrate close to the template.

6. The method according to claim 2, wherein the release information is information on a process that is affected by a pattern layout of the design pattern.

7. The method according to claim 6, wherein the release information is a releasing process parameter that affects a dimensional difference of the resist material before and after releasing that occurs when releasing the template from the resist material after filling of the resist material.

8. The method according to claim 2, wherein the filling information or the release information includes information on at least one of composition of the resist material, viscosity of the resist material, wettability of the resist material, an drop distribution of the resist material on the substrate, a pressure when the template is brought into contact with the resist material, a speed when the template is brought into contact with the resist material, a tilt when the template is brought into contact with the resist material, a release force when the template is released from the resist material, an adhesion force between the template and the resist material, and an adhesion force between the resist material and the substrate.

9. A method of generating a pattern comprising:
generating a template pattern to be formed on a template from a design pattern of a pattern above substrate formed by performing an imprint process using the template on a substrate;
obtaining the pattern above substrate by performing a process for forming the pattern above substrate by simulation or experiment based on the design pattern and the template pattern;
comparing the design pattern with obtained pattern above substrate and determining whether a comparison result satisfies a predetermined condition; and
employing the template pattern when the comparison result satisfies the predetermined condition and correcting the template pattern when the comparison result does not satisfy the predetermined condition.

10. The method according to claim 9, wherein the imprint process includes at least one of a process of forming the template pattern above the template, a wafer imprint process of forming a resist pattern by transferring the template pattern above a resist material applied on the substrate, and a processing process of processing a processing target film above the substrate by using the resist pattern.

11. The method according to claim 10, wherein the obtaining the pattern above substrate includes obtaining the pattern above substrate based on at least one of template manufacturing information on a manufacturing process of the template, filling information on a filling process of the resist material to be filled between the template and the substrate, release information on a releasing process of the template from the substrate, and processing bias information on a processing bias when processing the processing target film by using the resist pattern.

12. The method according to claim 11, wherein the template manufacturing information is information on a process that is affected by a pattern layout of the template pattern.

13. The method according to claim 11, wherein the filling information is information on a process that is affected by a pattern layout of the template pattern.

14. The method according to claim 13, wherein the filling information is a filling process parameter that affects a dimensional difference between the template pattern and a pattern of filled resist material.

15. The method according to claim 14, wherein the filling information includes a filling time required for the template to be filled with the resist material after bringing the resist material applied on the substrate close to the template.

16. The method according to claim 11, wherein the release information is information on a process that is affected by a pattern layout of the template pattern.

17. The method according to claim 16, wherein the release information is a releasing process parameter that affects a dimensional difference of the resist material before and after releasing that occurs when releasing the template from the resist material after filling of the resist material.

18. The method according to claim 11, wherein the filling information or the release information includes information on at least one of composition of the resist material, viscosity of the resist material, wettability of the resist material, an application distribution of the resist material on the substrate, a pressure when the template is brought into contact with the resist material, a speed when the template is brought into contact with the resist material, a tilt when the template is brought into contact with the resist material, a release force when the template is released from the resist material, an adhesion force between the template and the resist material, and an adhesion force between the resist material and the substrate.

19. A method of determining a process comprising:
preparing a design pattern of a pattern above substrate formed by performing an imprint process using a template on a substrate;
obtaining the pattern above substrate by performing the imprint process for forming the pattern above substrate by simulation or experiment based on the design pattern;
comparing the design pattern with obtained pattern above substrate and determining whether a comparison result satisfies a predetermined condition; and
employing the imprint process when the comparison result satisfies the predetermined condition and changing a condition of the imprint process when the comparison result does not satisfy the predetermined condition.

20. The method according to claim 19, wherein the obtaining the pattern above substrate includes obtaining the pattern above substrate based on at least one of filling information on a filling process of a resist material to be filled between the template and the substrate when performing the imprint process and release information on a releasing process of the template from the substrate performed when performing the imprint process.
